(19) United States
(12) Patent Application Publication
(10) Pub. No.: US 2023/0030963 A1
(43) Pub. Date: Feb. 2, 2023

(54) IMAGING APPARATUS AND METHOD FOR MANUFACTURING THE SAME

(71) Applicant: SONY SEMICONDUCTOR SOLUTIONS CORPORATION, KANAGAWA (JP)

(72) Inventor: ATSUSHI YAMAMOTO, KANAGAWA (JP)

(21) Appl. No.: 17/906,406

(22) PCT Filed: Jan. 27, 2021
(86) PCT No.: PCT/JP2021/002724

§ 371 Date: Sep. 15, 2022

(30) Foreign Application Priority Data
Mar. 23, 2020 (JP) 2020-050600

(51) Int. Cl. H04N 5/225; G02B 1/11; G02B 13/00; H01L 27/146

(52) U.S. Cl. CPC H04N 5/2254; G02B 1/11; G02B 13/0085; G02B 13/002; H01L 27/14623; H01L 27/14625; H01L 27/14685

(57) ABSTRACT

To suppress occurrence of flare and ghost while reducing the size or height of an imaging apparatus. The imaging apparatus is configured by mounting a cover structure on a solid-state imaging element. The solid-state imaging element generates a pixel signal by photoelectric conversion according to a light amount of incident light. The cover structure includes a non-flat surface for focusing incident light on a light receiving surface of the solid-state imaging element. The non-flat surface of the cover structure may have either a concave shape or a convex shape. It is assumed that the cover structure includes an inorganic material such as glass, silicon, or germanium.

### TECHNICAL FIELD

The present technology relates to an imaging apparatus. Specifically, the present technology relates to an imaging apparatus in which an optical element is configured on a solid-state imaging element and a method of manufacturing the same.

### BACKGROUND ART

In recent years, solid-state imaging elements used in mobile body terminal devices with cameras, digital still cameras, or the like have increasingly increased gained more pixels and been scaled down in size and height. With the increase in the number of pixels and the reduction in size of the camera, the lens and the solid-state imaging element are generally close to each other on an optical axis, and an infrared cut filter is generally disposed near the lens. For example, there has been proposed a technique for reducing the size of a solid-state imaging element by forming a lowermost lens in a lens group including a plurality of lenses on the solid-state imaging element (see, for example, Patent Document 1.).

### CITATION LIST

### Patent Document

Patent Document 1: Japanese Patent Application Laid-Open No. 2015-061193

### SUMMARY OF THE INVENTION

### Problems to be Solved by the Invention

In the above-described conventional technique, the lowermost lens is formed on the solid-state imaging element to downsize the solid-state imaging element. However, in a case where the lens is configured on the solid-state imaging element, although this contributes to size reduction and height reduction of the apparatus configuration, a distance between the infrared cut filter and the lens becomes short, and thus there is a possibility of a flare or a ghost caused by internal turbulence reflection due to reflection of light.

The present technology has been made in view of such a situation, and an object of the present technology is to suppress occurrence of the flare and the ghost while reducing the size or height of the imaging apparatus.

### Solutions to Problems

The present technology has been made to solve the problems described above, and a first aspect thereof is an imaging apparatus including a solid-state imaging element configured to generate a pixel signal by photoelectric conversion according to a light amount of incident light, and a cover structure having a non-flat surface for focusing the incident light on a light receiving surface of the solid-state imaging element, the cover structure being bonded to the solid-state imaging element via an adhesive, the cover structure being configured of an inorganic material. Therefore, by bonding the integrally formed cover structure to the solid-state imaging element, there is an effect of suppressing occurrence of flare and ghost while reducing the size or height of the imaging apparatus.

Furthermore, in the first aspect, the cover structure may be a wafer level lens. Therefore, it brings about an effect of reducing the size or height of the imaging apparatus.

Furthermore, in the first aspect, the cover structure may include glass, or may include silicon or germanium.

Furthermore, in the first aspect, the non-flat surface of the cover structure may have a shape obtained by cutting out an aspherical surface concentrically formed into a rectangular shape. Therefore, it brings about an effect of matching the shape of the non-flat surface with a pixel arrangement of the solid-state imaging element.

Furthermore, in the first aspect, the non-flat surface of the cover structure may have a concave shape. In this case, the cover structure may have a condition that a thickness of a thinnest portion is thinner than a height difference of a thickness on the non-flat surface. Furthermore, the cover structure may have a condition that the height difference of the thickness on the non-flat surface is thicker than the thickness of the solid-state imaging element. Therefore, it brings about an effect of improving performance as the non-flat surface lens while reducing the height of the cover structure.

Furthermore, in the first aspect, the non-flat surface of the cover structure may have a convex shape.

Furthermore, in the first aspect, the cover structure may include an anti-reflection coating on a surface thereof. Therefore, it brings about an effect of preventing ghost and flare due to surface reflection.

Furthermore, a second aspect of the present technology is a method for manufacturing an imaging apparatus, the method including a procedure of forming an inorganic material on an upper layer of a solid-state imaging element, and

a procedure of processing a surface of the inorganic material into a non-flat surface. Therefore, it brings about an effect of manufacturing the imaging apparatus with high image quality performance and reduced size or height.

Furthermore, in the second aspect, the procedure of processing the surface of the inorganic material into the non-flat surface may include a procedure of forming a degenerated layer on a surface of the inorganic material by laser processing or plasma processing, and

a procedure of removing the degenerated layer by etching.

Furthermore, in the second aspect, the procedure of processing the surface of the inorganic material into the non-flat surface may include a procedure of applying a photosensitive substance to the surface of the inorganic material and exposing the photosensitive substance to light and a procedure of removing an unnecessary portion of the surface of the inorganic material after exposure by etching.

Furthermore, in the second aspect, the procedure of processing the surface of the inorganic material into the non-flat surface may include a procedure of applying heat or light to deform the surface of the inorganic material, and

a procedure of removing an unnecessary portion after deformation of the surface of the inorganic material by etching. In this case, the etching may be catalytic etching.

### BRIEF DESCRIPTION OF DRAWINGS

FIG. 1 is a diagram depicting an external configuration example of an imaging apparatus according to an embodiment of the present technology.

FIG. 2 is a diagram depicting a cross-sectional configuration example of the imaging apparatus according to the embodiment of the present technology.

FIG. 3 is a diagram depicting another shape example of a cover structure 400 having a concave shape according to the embodiment of the present technology.

FIG. 4 is a diagram depicting a first modification example of a structure of a non-flat surface end portion of the cover structure 400 having a concave shape according to the embodiment of the present technology.

FIG. 5 is a diagram depicting a second modification example of the structure of the non-flat surface end portion of the cover structure 400 having a concave shape according to the embodiment of the present technology.

FIG. 6 is a diagram depicting a third modification example of the structure of the non-flat surface end portion of the cover structure 400 having a concave shape according to the embodiment of the present technology.

FIG. 7 is a diagram depicting a fourth modification example of the structure of the non-flat surface end portion of the cover structure 400 having a concave shape according to the embodiment of the present technology.

FIG. 8 is a diagram depicting a first modification example of the structure of the non-flat surface of the cover structure 400 having a concave shape according to the embodiment of the present technology.

FIG. 9 is a diagram depicting a second modification example of the structure of the non-flat surface of the cover structure 400 having a concave shape according to the embodiment of the present technology.

FIG. 10 is a diagram depicting a shape example of the cover structure 400 having a convex shape according to the embodiment of the present technology.

FIG. 11 is a diagram depicting a first example of a method for manufacturing the imaging apparatus according to the embodiment of the present technology.

FIG. 12 is a diagram depicting a second example of the method for manufacturing the imaging apparatus according to the embodiment of the present technology.

FIG. 13 is a diagram depicting a third example of the method for manufacturing the imaging apparatus according to the embodiment of the present technology.

FIG. 14 is a diagram depicting a fourth example of the method for manufacturing the imaging apparatus according to the embodiment of the present technology.

FIG. 15 is a diagram depicting a fifth example of the method for manufacturing the imaging apparatus according to the embodiment of the present technology.

FIG. 16 is a diagram depicting a sixth example of the method for manufacturing the imaging apparatus according to the embodiment of the present technology.

FIG. 17 is a diagram depicting a seventh example of the method for manufacturing the imaging apparatus according to the embodiment of the present technology.

FIG. 18 is a diagram depicting an eighth example of the method for manufacturing the imaging apparatus according to the embodiment of the present technology.

FIG. 19 is a diagram depicting a ninth example of the method for manufacturing the imaging apparatus according to the embodiment of the present technology.

FIG. 20 is a diagram depicting a tenth example of the method for manufacturing the imaging apparatus according to the embodiment of the present technology.

FIG. 21 is a diagram depicting an eleventh example of the method for manufacturing the imaging apparatus according to the embodiment of the present technology.

FIG. 22 is a diagram depicting a twelfth example of the method for manufacturing the imaging apparatus according to the embodiment of the present technology.

FIG. 23 is a diagram depicting a thirteenth example of the method for manufacturing the imaging apparatus according to the embodiment of the present technology.

FIG. 24 is a diagram depicting a configuration example of an imaging apparatus 1 to which an embodiment of the present technology is applicable.

FIG. 25 is a diagram depicting a configuration example of an integrated configuration unit 10 of the imaging apparatus 1 to which the embodiment of the present technology is applicable.

FIG. 26 is a diagram depicting an aspect example of lamination of the imaging apparatus 1 to which the embodiment of the present technology is applicable.

FIG. 27 is a diagram depicting a configuration example of a solid-state imaging element 11 of an imaging apparatus 1 to which an embodiment of the present technology is applicable.

FIG. 28 is a diagram depicting an equivalent circuit of a pixel 32 of the imaging apparatus 1 to which the embodiment of the present technology is applicable.

FIG. 29 is an example of a cross-sectional view of the solid-state imaging element 11 of the imaging apparatus 1 to which an embodiment of the present technology is applicable.

FIG. 30 is an example of a cross-sectional view of another solid-state imaging element of an imaging apparatus to which an embodiment of the present technology is applicable.

FIG. 31 is a block diagram depicting a configuration example of an imaging apparatus 1001 as electronic equipment to which the present technology is applicable.

FIG. 32 is a diagram depicting an application example of an imaging apparatus as electronic equipment to which the present technology is applicable.

FIG. 33 is a diagram depicting an example of a schematic configuration of an endoscopic surgery system.

FIG. 34 is a block diagram depicting an example of a functional configuration of a camera head and a CCU.

FIG. 35 is a block diagram depicting an example of schematic configuration of a vehicle control system.

FIG. 36 is an explanatory diagram of an example of installation positions of an outside-vehicle information detecting section and an imaging section.

### MODE FOR CARRYING OUT THE INVENTION

Hereinafter, modes for carrying out the present technology (hereinafter, referred to as an embodiment) will be described. The description will be given in the following order.

1. Embodiments

2. Modification Example

3. Applicable Example

4. Application Example

### 1. EMBODIMENT

[Imaging Apparatus]

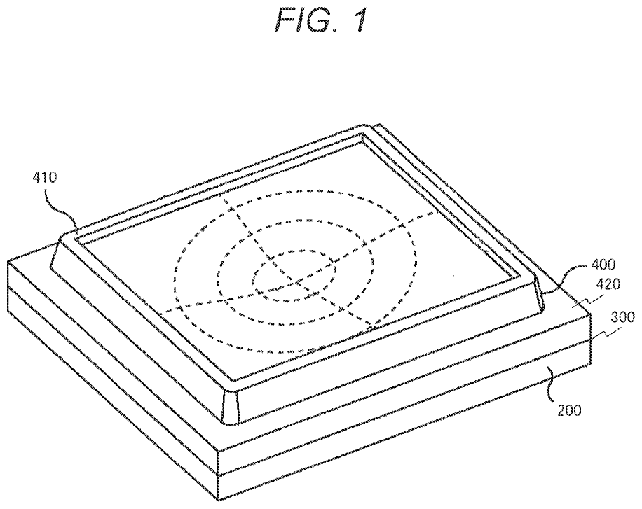

FIG. 1 is a diagram depicting an external configuration example of an imaging apparatus according to an embodiment of the present technology.

This imaging apparatus has a structure in which a cover structure 400 is bonded onto a solid-state imaging element 200. The solid-state imaging element 200 and the cover structure 400 are bonded via an adhesive 300. The adhesive 300 desirably has substantially the same refractive index as the cover structure 400. The solid-state imaging element 200 generates a pixel signal by photoelectric conversion according to a light amount of incident light.

The cover structure 400 includes a non-flat surface for focusing incident light on a light receiving surface of the solid-state imaging element 200. The cover structure 400 has a function as a lens that refracts or diverges light in addition to a function as a cover of the solid-state imaging element 200. That is, the cover structure 400 can be considered to be formed by integrally molding the lens and the cover of the solid-state imaging element 200 with the same material without using an adhesive. That is, the cover structure 400 can be realized as a wafer level lens. As described above, by forming the laminate into an integrated form, it is possible to maintain the strength even when the thickness is reduced, and for example, the thickness can be reduced by about 40 to 50 microns, and the height can be reduced.

The cover structure 400 includes an inorganic material. Specifically, a metal material or ceramics such as glass is assumed. In the case of a metal material, it is desirable to use silicon or germanium that can transmit a long wavelength. As described above, by using the inorganic material as the material of the cover structure 400, volume expansion against a thermal load can be suppressed, and reliability resistance can be improved. Furthermore, by using a material having substantially the same thermal expansion coefficient as the material of the solid-state imaging element 200 as the material of the cover structure 400, occurrence of warpage can be suppressed, connection failure can be prevented, and as a result, image quality of an image can be improved. Furthermore, also in the manufacturing process, since singulation is easier than with the organic material, the effective range of the non-flat surface that functions as the lens can be expanded.

Furthermore, an anti-reflection coating may be formed on a surface of the cover structure 400 on which light is incident. Therefore, it makes it possible to prevent ghost and flare due to surface reflection.

The cover structure 400 includes a protrusion 410 and an overhang 420 around the non-flat surface. Note that, as will be described later, a structure in which the protrusion 410 and the overhang 420 are not provided can also be formed.

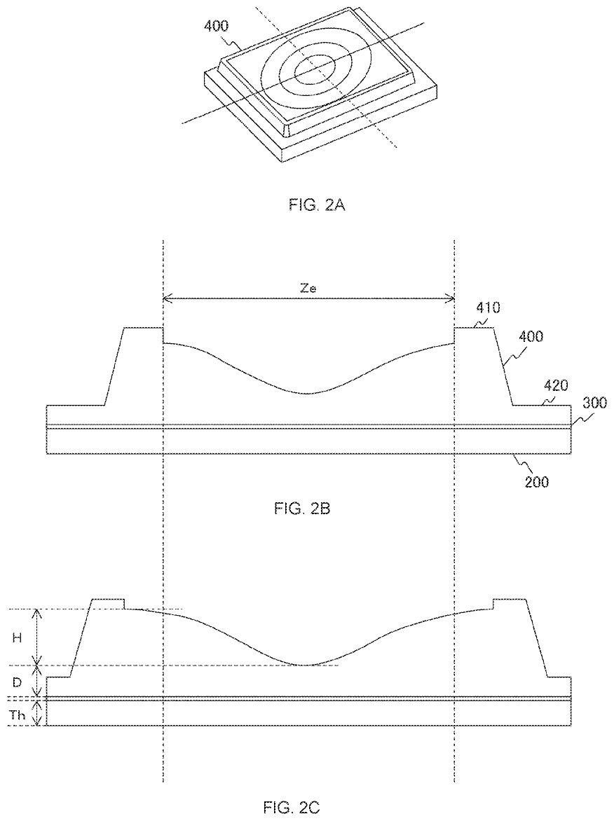

FIG. 2 is a diagram depicting a cross-sectional configuration example of the imaging apparatus according to the embodiment of the present technology. In the drawing, b illustrates a cross-sectional shape in a direction indicated by a dotted line in the drawing. In the drawing, c illustrates a cross-sectional shape in a direction indicated by a solid line in the drawing.

The upper surface of the cover structure 400 has a conical shape having an aspherical concave shape centered on the center of gravity as viewed from the upper surface. That is, the upper surface of the cover structure 400 has a shape obtained by cutting out an aspherical surface concentrically formed into a rectangular shape. The rectangular shape of the non-flat surface in this case is assumed to be a rectangle having a different aspect ratio in consideration of a general pixel array.

In the drawing, b and c have a common aspherical curved surface structure in the range Ze, and such a shape constitutes an effective region for condensing incident light from above on the imaging surface of the solid-state imaging element 200.

Furthermore, since the cover structure 400 includes an aspherical curved surface, the thickness varies depending on the distance from the center of the effective region. More specifically, the center position has a thickness D of the thinnest portion. Furthermore, the thickness of the end of the non-flat surface is the largest, and the following equation is established with respect to the height difference H of the thickness in the non-flat surface.

H>D

Furthermore, when the thickness of the solid-state imaging element 200 is denoted by Th, the following equation is established.

H>Th

Using the cover structure 400 and the solid-state imaging element 200 that satisfy these conditional expressions, it is possible to reduce the size and height of an imaging apparatus capable of imaging with high resolution.

### 2. MODIFICATION EXAMPLE

### Modification Example of Concave Shape of Non-Flat Surface

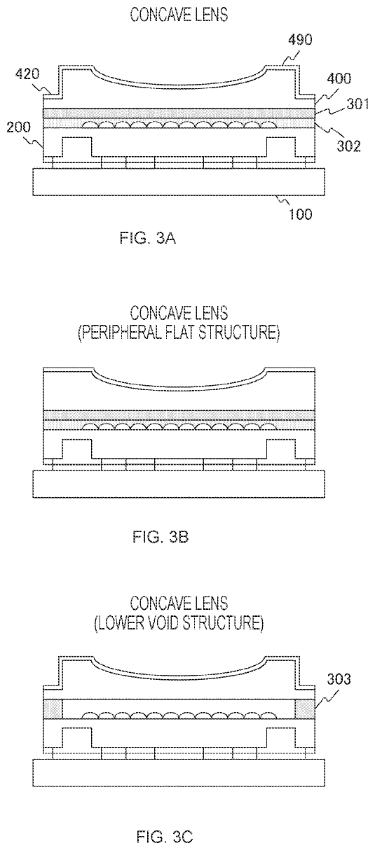

FIG. 3 is a diagram depicting another shape example of a cover structure 400 having a concave shape according to the embodiment of the present technology.

In the above-described embodiment, as the shape of the cover structure 400, a shape having a concave shape and including the protrusion 410 and the overhang 420 is assumed, but this is an example, and various shapes are conceivable as follows.

For example, as depicted in a of the drawing, the protrusion 410 may not be provided, and the overhang 420 may be provided. Note that, in the drawing and the following example, the solid-state imaging element 200 is formed on the substrate 100. Furthermore, an adhesive 302 is provided on the upper surface of the on-chip lens of the solid-state imaging element 200, and the cover structure 400 is bonded thereon via the adhesive 301. Furthermore, an anti-reflection coating 490 is formed on a surface of the cover structure 400 on which light is incident.

Furthermore, as depicted in b of the drawing, the protrusion 410 and the overhang 420 may not be provided, and the peripheral region may have a flat structure. Therefore, it makes it possible to relatively expand the effective region.

Furthermore, as depicted in c of the drawing, a structure in which bonding with the adhesive 303 is performed only in the pixel peripheral portion, and a gap (air layer) is provided on the incident light side of the upper surface of the on-chip lens of the solid-state imaging element 200 may be adopted.

### Modification Example of Structure of Non-Flat Surface End Portion

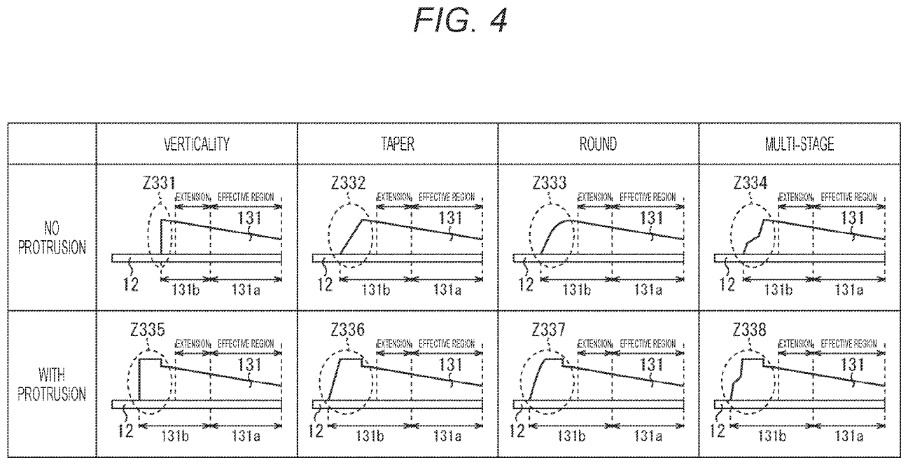

FIG. 4 is a diagram depicting a first modification example of a structure of the non-flat surface end portion of the cover structure 400 having a concave shape according to the embodiment of the present technology.

The example in which the end portion of the cover structure 400 is formed perpendicular to the imaging surface of the solid-state imaging element 200 has been described above. However, as long as the size of the cover structure 400 is set to be smaller than the size of the solid-state imaging element 200, an effective region 131a is set at the central portion of the cover structure 400, and a non-effective region 131b is set at the outer peripheral portion thereof, the cover structure may be formed in other shapes. Note that, in the following drawings, the overhang 420 is depicted as an overhang 12.

That is, as depicted in the upper left part of the drawing, at the boundary between the non-effective region 131b and the effective region 131a, the configuration similar to that of the effective region 131a as an aspherical lens may be extended, and the end portion may be formed vertically as depicted by an end portion 2331 of the non-effective region 131b.

Furthermore, as depicted in the second upper part from the left in the drawing, at the boundary between the non-effective region 131b and the effective region 131a, the configuration similar to that of the effective region 131a as the aspherical lens may be extended, and the end portion may be formed in a tapered shape as depicted by an end portion 2332 of the non-effective region 131b.

Furthermore, as depicted in the third upper part from the left in the drawing, at the boundary between the non-effective region 131b and the effective region 131a, the configuration similar to that of the effective region 131a as the aspherical lens may be extended, and the end portion may be formed in a round shape as depicted by an end portion 2333 of the non-effective region 131b.

Furthermore, as depicted in the upper right part of the drawing, at the boundary between the non-effective region 131b and the effective region 131a, the configuration similar to the effective region 131a as the aspherical lens may be extended, and the end portion may be formed as the side surface having a multi-stage structure as depicted by the end portion 2334 of the non-effective region 131b.

Furthermore, as depicted in the lower left part of the drawing, the configuration similar to the effective region 131a as the aspherical lens may be extended at the boundary with the effective region 131a in the non-effective region 131b, and as depicted by the end portion 2335 of the non-effective region 131b, a horizontal plane portion may be provided at the end portion, a bank-shaped protrusion protruding in a direction facing the incident direction of the incident light may be formed more than the effective region 131a, and the side surface of the protrusion may be formed vertically.

Furthermore, as depicted in the second lower part from the left in the drawing, the configuration similar to that of the effective region 131a as the aspherical lens may be extended at the boundary with the effective region 131a in the non-effective region 131b, and as depicted by the end portion 2336 of the non-effective region 131b, a horizontal plane portion may be provided at the end portion, a bank-shaped protrusion protruding in a direction facing the incident direction of the incident light may be formed more than the effective region 131a, and the side surface of the protrusion may be formed in a tapered shape.

Furthermore, as depicted in the third lower part from the left in the drawing, the configuration similar to that of the effective region 131a as the aspherical lens may be extended at the boundary with the effective region 131a in the non-effective region 131b, and as depicted by the end portion 2337 of the non-effective region 131b, a horizontal plane portion may be provided at the end portion, a bank-shaped protrusion protruding in a direction facing the incident direction of the incident light may be formed more than the effective region 131a, and the side surface of the protrusion may be formed in a round shape.

Furthermore, as depicted in the lower right part of the drawing, the configuration similar to that of the effective region 131a as the aspherical lens may be extended at the boundary with the effective region 131a in the non-effective region 131b, and as depicted by the end portion 2338 of the non-effective region 131b, a horizontal plane portion may be provided at the end portion, a bank-shaped protrusion protruding in a direction facing the incident direction of the incident light may be formed more than the effective region 131a, and the side surface of the protrusion may be formed in a multi-stage structure.

Note that, in the upper part of the drawing, a structural example in which a horizontal plane portion is provided at the end portion of an aspherical lens, and a bank-shaped projecting portion projecting from the effective region 131a in a direction opposite to the incident direction of the incident light is not provided is depicted and in the lower part of the drawing, a structural example in which the end portion of the cover structure 400 is not provided with a protrusion having a horizontal plane portion is depicted. Furthermore, an example in which the end portion of the aspherical lens is configured vertically, an example in which the end portion is configured in a tapered shape, an example in which the end portion is configured in a round shape, and an example in which the end portion of the plurality of the side surface is configured in multi-stages are depicted in the upper stage and the lower stage of the drawing in order from the left.

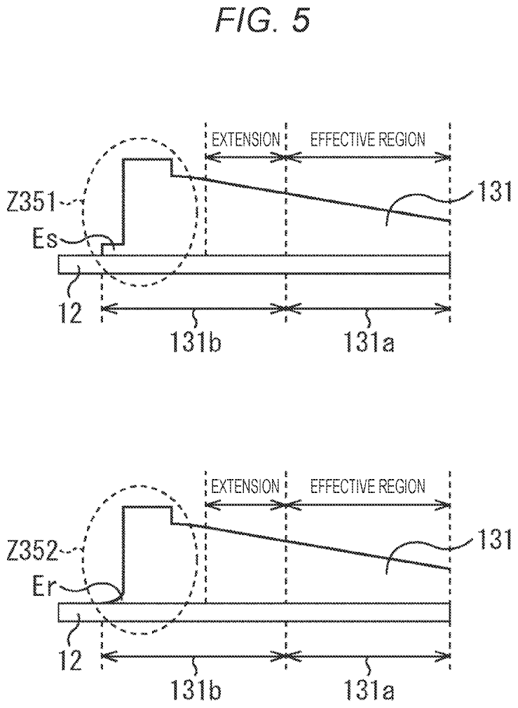

FIG. 5 is a diagram depicting a second modification example of the structure of the non-flat surface end portion of the cover structure 400 having a concave shape according to the embodiment of the present technology.

As depicted in the upper part of the drawing, a configuration similar to that of the effective region 131a as an aspherical lens may be extended at the boundary between the non-effective region 131b and the effective region 131a, and as depicted by the end portion 2351 of the non-effective region 131b, a protrusion may be formed vertically, and a rectangular boundary structure Es may be left at the boundary with the overhang 12.

Furthermore, as depicted in the lower part of the drawing, a configuration similar to that of the effective region 131a as an aspherical lens may be extended at the boundary between the non-effective region 131b and the effective region 131a, and as depicted by the end portion 2352 of the non-effective region 131b, a protrusion is formed vertically, and moreover, a boundary structure Er having the round shape may be left at the boundary with the overhang 12.

Note that the rectangular boundary structure Es and the round boundary structure Er may be used in any of a case where the end portion is formed in a tapered shape, a case where the end portion is formed in a round shape, and a case where the end portion is formed in a multistage structure.

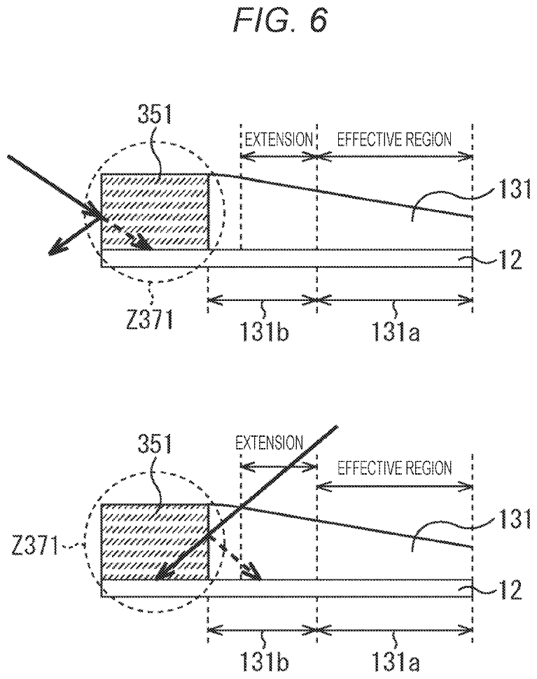

FIG. 6 is a diagram depicting a third modification example of the structure of the non-flat surface end portion of the cover structure 400 having a concave shape according to the embodiment of the present technology. In the following drawings, a portion as a lens of the cover structure 400 is depicted as a lens 131.

As depicted in the drawing, a configuration similar to that of the effective region 131a as an aspherical lens may be extended at a boundary with the effective region 131a in the non-effective region 131b, a side surface of the lens 131 may be formed vertically as indicated by an end portion 2371 of the non-effective region 131b, and the refractive film 351 having a predetermined refractive index may be formed on the overhang 12 at substantially the same height as the side surface of the lens 131.

Therefore, for example, in a case where the refractive film 351 has a refractive index higher than the predetermined refractive index, as indicated by a solid arrow in the upper part of the drawing, in a case where there is incident light from the outer peripheral portion of the lens 131, the incident light is reflected to the outside of the lens 131, and as indicated by a dotted arrow, the incident light to the side surface portion of the lens 131 is reduced. As a result, since entry of stray light into the lens 131 is suppressed, occurrence of flare and ghost is suppressed.

Furthermore, in a case where the refractive film 351 has a refractive index lower than the predetermined refractive index, light that is not incident on the incident surface of the solid-state imaging element 200 and is to be transmitted from the side surface of the lens 131 to the outside of the lens 131 is transmitted as indicated by a solid arrow in the lower part of the drawing, and reflected light from the side surface of the lens 131 is reduced as indicated by a dotted arrow. As a result, since entry of stray light into the lens 131 is suppressed, occurrence of flare and ghost can be suppressed.

Furthermore, in the drawing, an example has been described in which the refractive film 351 is formed at the same height as the lens 131 and has an end portion formed vertically. However, as described below, the refractive film may have other shapes.

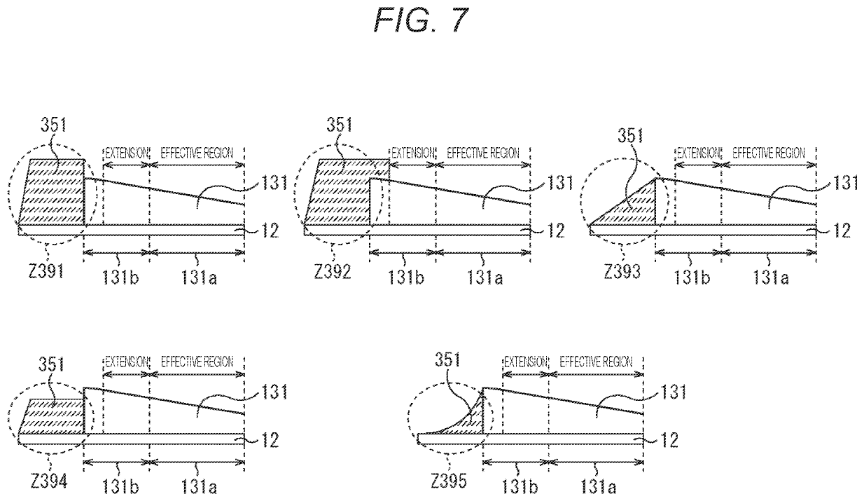

FIG. 7 is a diagram depicting a fourth modification example of the structure of the non-flat surface end portion of the cover structure 400 having a concave shape according to the embodiment of the present technology.

As depicted in an upper left part region 2391 in the drawing, the refractive film 351 may be configured to have a tapered shape is formed at the upper end portion of the overhang 12 and have the thickness higher than the height of the end portion of the lens 131.

Furthermore, as depicted in a region 2392 at the upper center in the drawing, the refractive film 351 may be configured to have a tapered shape at the end portion and have a thickness higher than the height of the end portion of the lens 131, and may be configured to partially cover the non-effective region 131b of the lens 131.

Furthermore, as depicted in an upper right region 2393 in the drawing, the refractive film 351 may be configured to have a tapered shape from the height of the end portion of the lens 131 to the end portion of the overhang 12.

Furthermore, as depicted in a lower left region 2394 in the drawing, the refractive film 351 may be configured to have a tapered shape at the end portion of the overhang 12 and a thickness lower than the height of the end portion of the lens 131.

Furthermore, as depicted in a lower right region 2395 in the drawing, the refractive film 351 may be configured to have a concave shape toward the overhang 12 with respect to the height of the end portion of the lens 131 and in a round shape.

In any configuration in which refractive film 351 is provided, the stray light is prevented from entering lens 131, so that occurrence of flare and ghost can be prevented.

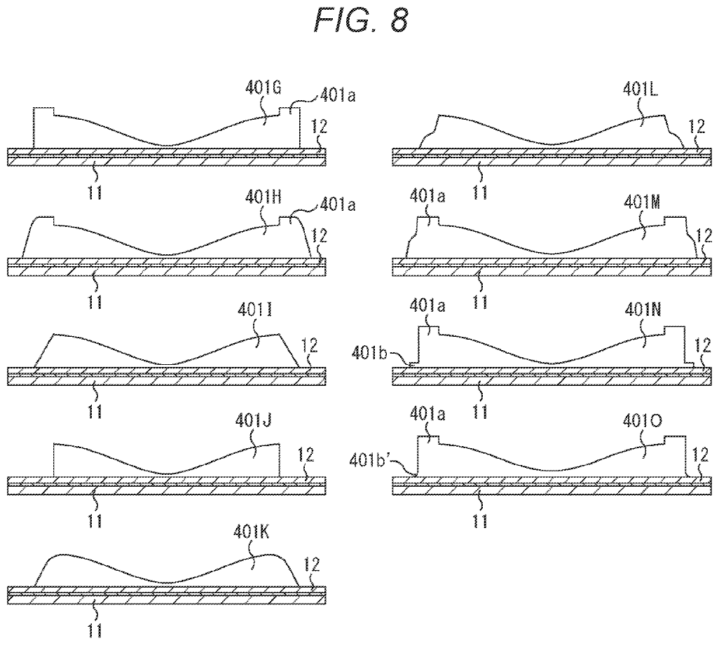

FIG. 8 is a diagram depicting a first modification example of the structure of the non-flat surface of the cover structure 400 having a concave shape according to the embodiment of the present technology. Note that, in the following drawings, the solid-state imaging element 200 is depicted as a solid-state imaging element 11.

As depicted in a lens 401G in the drawing, the side surface on the outer peripheral side of a protrusion 401a may be configured to form a right angle with respect to a glass substrate 12, and may be configured not to include a taper.

Furthermore, as depicted in a lens 401H in the drawing, the side surface on the outer peripheral side of the protrusion 401a may include a round taper.

Furthermore, as indicated by a lens 401I in the drawing, the protrusion 401a itself may not be included, and the side surface may have a linear tapered shape forming a predetermined angle with respect to the glass substrate 12.

Furthermore, as depicted in a lens 401J in the drawing, a configuration may be employed in which the protrusion 401a itself is not included, and the side surface forms a right angle with respect to the glass substrate 12, and the tapered shape is not included.

Furthermore, as depicted in a lens 401K in the drawing, the protrusion 401a itself may not be included, and the side surface may have a round tapered shape with respect to the glass substrate 12.

Furthermore, as depicted in a lens 401L in the drawing, the protrusion 401a itself may not be included, and the side surface of the lens may have a two-stage configuration having two inflection points.

Furthermore, as depicted in a lens 401M in the drawing, a two-stage configuration may be employed in which the side surface includes a protrusion 401a and has two inflection points on the outer side surface.

Furthermore, as depicted in a lens 401N in the drawing, the protrusion 401a may be included, and the side surface may form a right angle, and moreover, a rectangular fringe portion 401b may be further added in the vicinity of the boundary with the glass substrate 12.

Furthermore, as depicted in a lens 401O in the drawing, the protrusion 401a may be included, and a fringe portion 401b′ having a round shape may be further added near a boundary with the overhang 12 as a configuration forming a right angle with respect to the glass substrate 12.

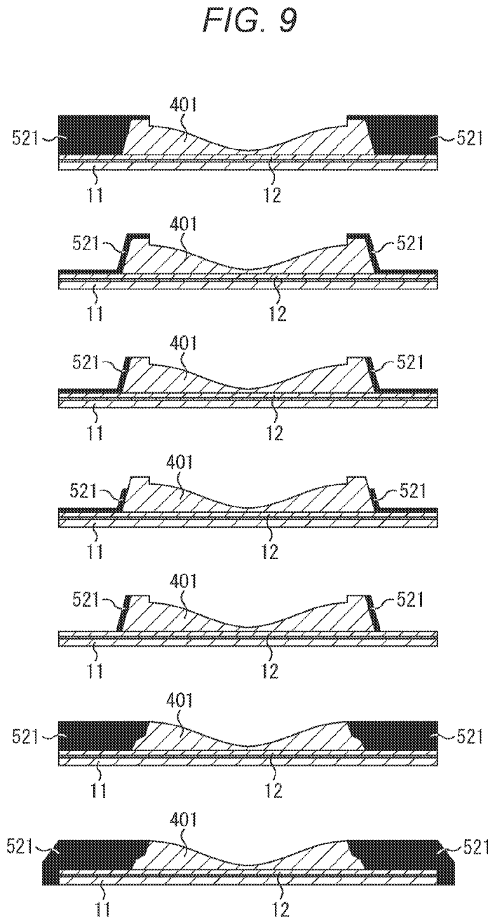

FIG. 9 is a diagram depicting a second modification example of the structure of the non-flat surface of the cover structure 400 having a concave shape according to the embodiment of the present technology.

As depicted at the uppermost stage in the drawing, on the overhang 12, a light shielding film 521 may be formed in the entire range up to the height of the side surface of a lens 401 and the flat portion of the upper surface of the protrusion, that is, in a range other than the effective region.

Furthermore, as depicted second at the from the top in the drawing, the light shielding film 521 may be formed on the entire surface from the overhang 12 to the side surface of the lens 401 and the planar portion of the upper surface of the protrusion, that is, the entire surface portion other than the effective region.

Furthermore, as depicted at the third from the top in the drawing, the light shielding film 521 may be formed on the side surface of the protrusion of the lens 401 from above the overhang 12.

Furthermore, as depicted at the fourth from the top in the drawing, the light shielding film 521 may be formed in a range from the overhang 12 to a predetermined height on the side surface of the protrusion of the lens 401 from above the overhang 12.

Furthermore, as depicted at the fifth position from the top in the drawing, the light shielding film 521 may be formed only on the side surface of the protrusion of the lens 401.

Furthermore, as depicted at the sixth position from the top in the drawing, the light shielding film 521 may be formed in a range up to the highest position of the two side surfaces of the two-stage side surface type lens 401 on the overhang 12.

Furthermore, as depicted at the seventh position from the top in the drawing, the light shielding film 521 may be formed to cover the entire surface up to the highest position of the two side surfaces of the two-stage side surface type lens 401 on the overhang 12 and the outer peripheral portion of the solid-state imaging element 11.

Note that, in any example, the light shielding film 521 is formed by partial film formation, formed by lithography after film formation, formed by forming a resist after forming a film, and formed by lifting off the resist, or formed by lithography.

Furthermore, a bank for forming a light shielding film may be formed on the outer peripheral portion of the two-stage side surface type lens 401, and the light shielding film 521 may be formed on the outer peripheral portion of the two-stage side surface type lens 401 and inside the bank.

### Modification Example of Convex Shape of Non-Flat Surface

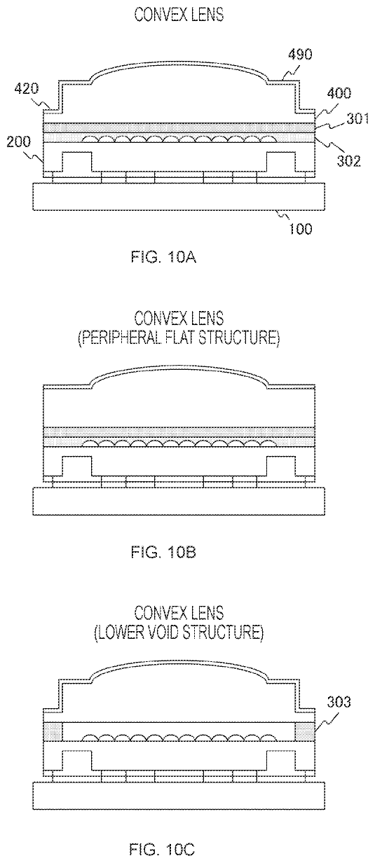

FIG. 10 is a diagram depicting a shape example of the cover structure 400 having a convex shape according to the embodiment of the present technology.

In the above-described embodiment, a concave shape is assumed as the shape of the non-flat surface of the cover structure 400, but the non-flat surface may have a convex shape.

For example, as depicted in a of the drawing, the non-flat surface may have a convex shape, and may have a shape including the overhang 420.

Furthermore, as depicted in b of the drawing, the overhang 420 may not be provided, and the peripheral region may have a flat structure. Therefore, it makes it possible to relatively expand the effective region.

Furthermore, as depicted in c of the drawing, a structure in which bonding with the adhesive 303 is performed only in the pixel peripheral portion, and a gap is provided on the incident light side of the upper surface of the on-chip lens of the solid-state imaging element 200 may be adopted.

[Manufacturing Method]

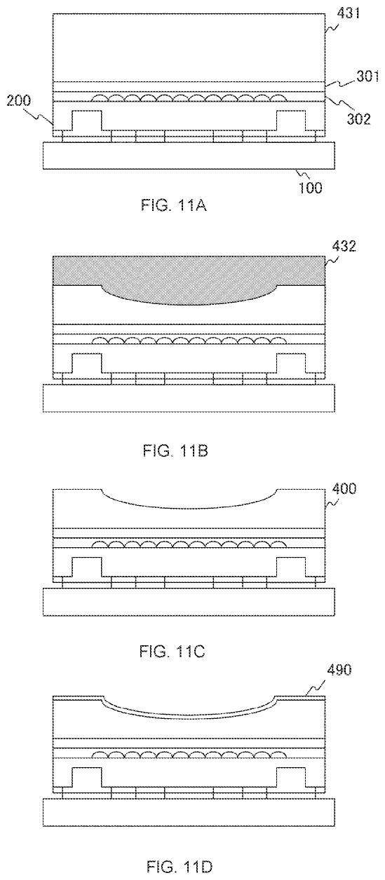

FIG. 11 is a diagram depicting a first example of the method for manufacturing the imaging apparatus according to the embodiment of the present technology. The first example shows an example in which the cover structure 400 having a concave shape is formed using laser processing or plasma processing.

First, as depicted in a of the drawing, an inorganic material 431 for forming the cover structure 400 is provided on the upper surface of the solid-state imaging element 200 via adhesives 302 and 301.

Then, as depicted in b of the drawing, a degenerated layer 432 is formed on the surface of the inorganic material 431 by laser processing or plasma processing.

Then, as depicted in c in the drawing, the degenerated layer 432 is removed by wet etching back or dry etching.

Thereafter, as depicted in d in the drawing, an anti-reflection coating 490 is formed on the surface of the cover structure 400.

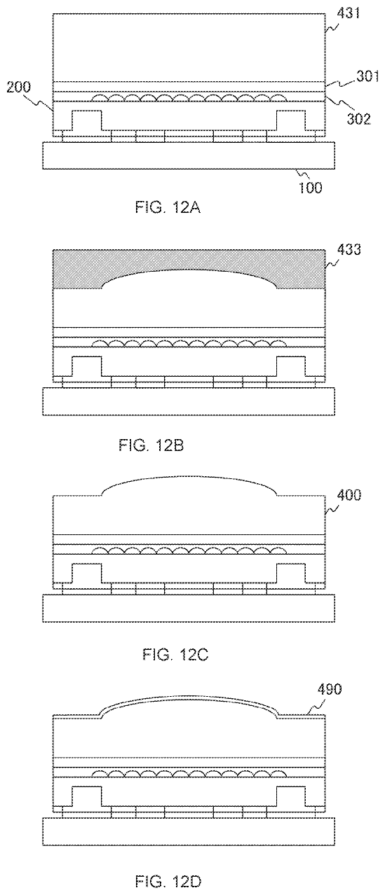

FIG. 12 is a diagram depicting a second example of the method for manufacturing the imaging apparatus according to the embodiment of the present technology. The second example shows an example in which the cover structure 400 having a convex shape is formed using laser processing or plasma processing.

First, as depicted in a of the drawing, an inorganic material 431 for forming the cover structure 400 is provided on the upper surface of the solid-state imaging element 200 via adhesives 302 and 301.

Then, as depicted in b of the drawing, a degenerated layer 433 is formed on the surface of the inorganic material 431 by laser processing or plasma processing.

Then, as depicted in c in the drawing, the degenerated layer 433 is removed by wet etching back or dry etching.

Thereafter, as depicted in d in the drawing, an anti-reflection coating 490 is formed on the surface of the cover structure 400.

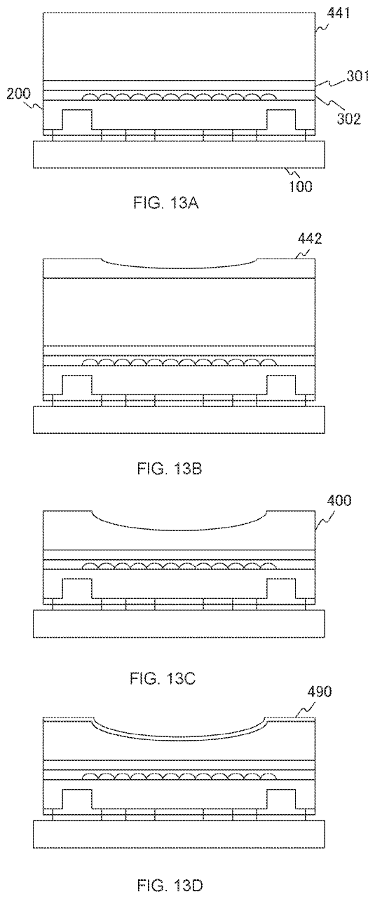

FIG. 13 is a diagram depicting a third example of the method for manufacturing the imaging apparatus according to the embodiment of the present technology. In the third example, an example is depicted in which the cover structure 400 having a concave shape is formed using lithography and etching. Note that the third example is applicable to any of a metal material and glass as a material of the cover structure 400.

First, as depicted in a of the drawing, an inorganic material 441 for forming the cover structure 400 is provided on the upper surface of the solid-state imaging element 200 via adhesives 302 and 301.

Then, as depicted in b of the drawing, a gray tone mask 442 is formed on the surface of the inorganic material 441 by lithography, and exposure is performed.

Then, as depicted in c in the drawing, an unnecessary portion after exposure of the surface of the inorganic material 441 is removed by dry etching.

Thereafter, as depicted in d in the drawing, an anti-reflection coating 490 is formed on the surface of the cover structure 400.

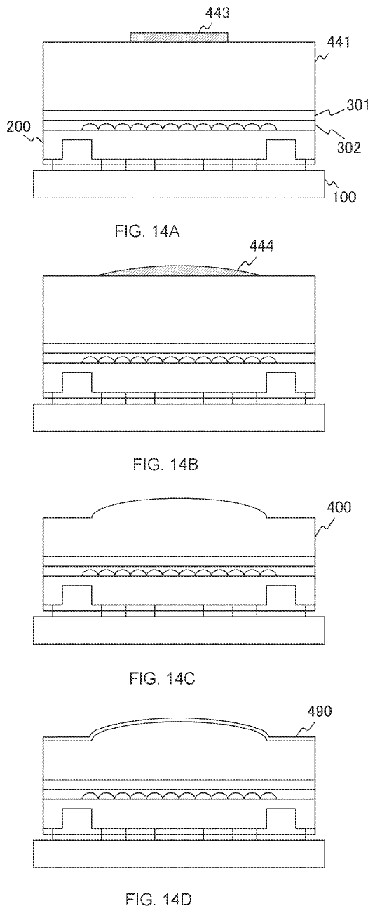

FIG. 14 is a diagram depicting a fourth example of the method for manufacturing the imaging apparatus according to the embodiment of the present technology. In the fourth example, a first example is depicted in which the cover structure 400 having a convex shape is formed using lithography and etching. Note that the fourth example is applicable to any of a metal material and glass as a material of the cover structure 400.

First, as depicted in a of the drawing, an inorganic material 441 for forming the cover structure 400 is provided on the upper surface of the solid-state imaging element 200 via adhesives 302 and 301, and a photosensitive resin 443 is applied for lithography.

Then, as depicted in b of the drawing, flow baking is performed to form a mask 444, and exposure is performed.

Then, as depicted in c in the drawing, an unnecessary portion after exposure of the surface of the inorganic material 441 is removed by dry etching.

Thereafter, as depicted in d in the drawing, an anti-reflection coating 490 is formed on the surface of the cover structure 400.

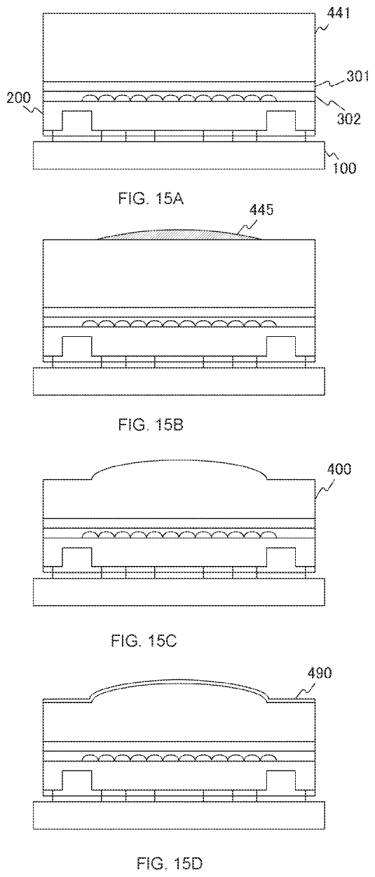

FIG. 15 is a diagram depicting a fifth example of the method for manufacturing the imaging apparatus according to the embodiment of the present technology. In the fifth example, a second example is depicted in which the cover structure 400 having a convex shape is formed using lithography and etching. Note that the fifth example is applicable to any of a metal material and glass as a material of the cover structure 400.

First, as depicted in a of the drawing, an inorganic material 441 for forming the cover structure 400 is provided on the upper surface of the solid-state imaging element 200 via adhesives 302 and 301.

Then, as depicted in b of the drawing, a gray tone mask 445 is formed on the surface of the inorganic material 441 by lithography, and exposure is performed.

Then, as depicted in c in the drawing, an unnecessary portion after exposure of the surface of the inorganic material 441 is removed by dry etching.

Thereafter, as depicted in d in the drawing, an anti-reflection coating 490 is formed on the surface of the cover structure 400.

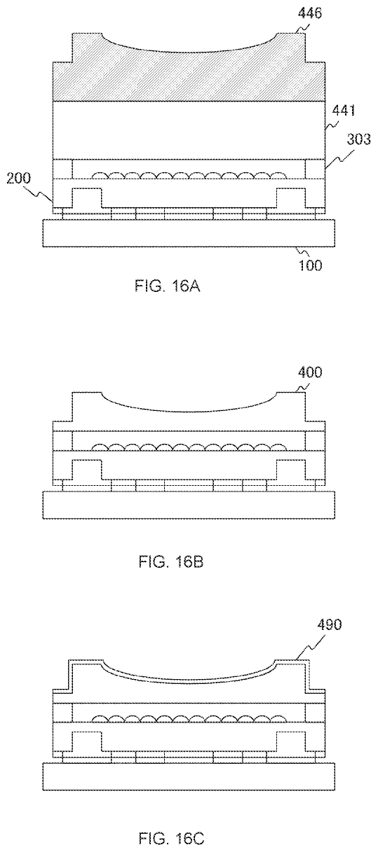

FIG. 16 is a diagram depicting a sixth example of the method for manufacturing the imaging apparatus according to the embodiment of the present technology. In the sixth example, a first example in which the cover structure 400 having a concave shape is formed using lithography and etching to manufacture an imaging apparatus having a void structure is shown.

First, as depicted in a of the drawing, the inorganic material 441 for forming the cover structure 400 is provided on the upper surface of the solid-state imaging element 200 via the adhesive 303, and a gray tone mask 446 is formed on the surface of the inorganic material 441 by lithography to perform exposure.

Then, as depicted in b in the drawing, an unnecessary portion after exposure of the surface of the inorganic material 441 is removed by dry etching.

Thereafter, as depicted in c in the drawing, an anti-reflection coating 490 is formed on the surface of the cover structure 400.

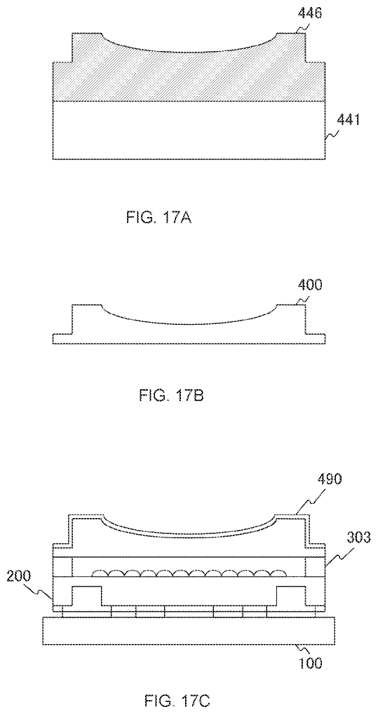

FIG. 17 is a diagram depicting a seventh example of the method for manufacturing the imaging apparatus according to the embodiment of the present technology. In the seventh example, a second example in which the cover structure 400 having a concave shape is formed using lithography and etching to manufacture an imaging apparatus having a void structure is shown.

First, as depicted in a of the drawing, the inorganic material 441 for forming the cover structure 400 is provided, and the gray tone mask 446 is formed on the surface of the inorganic material 441 by lithography to perform exposure.

Then, as depicted in b in the drawing, an unnecessary portion after exposure of the surface of the inorganic material 441 is removed by dry etching. That is, the cover structure 400 is formed as a separate body.

Thereafter, as depicted in c of the drawing, the cover structure 400 is bonded to the upper surface of the solid-state imaging element 200 via the adhesive 303, and the anti-reflection coating 490 is formed on the surface of the cover structure 400.

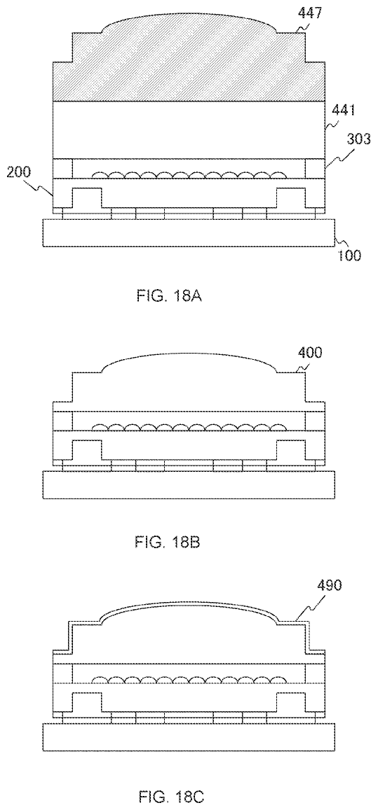

FIG. 18 is a diagram depicting an eighth example of the method for manufacturing the imaging apparatus according to the embodiment of the present technology. In the eighth example, a first example in which the cover structure 400 having a convex shape is formed using lithography and etching to manufacture an imaging apparatus having a void structure is shown.

First, as depicted in a of the drawing, the inorganic material 441 for forming the cover structure 400 is provided on the upper surface of the solid-state imaging element 200 via the adhesive 303, and a gray tone mask 447 is formed on the surface of the inorganic material 441 by lithography to perform exposure.

Then, as depicted in b in the drawing, an unnecessary portion after exposure of the surface of the inorganic material 441 is removed by dry etching.

Thereafter, as depicted in c in the drawing, an anti-reflection coating 490 is formed on the surface of the cover structure 400.

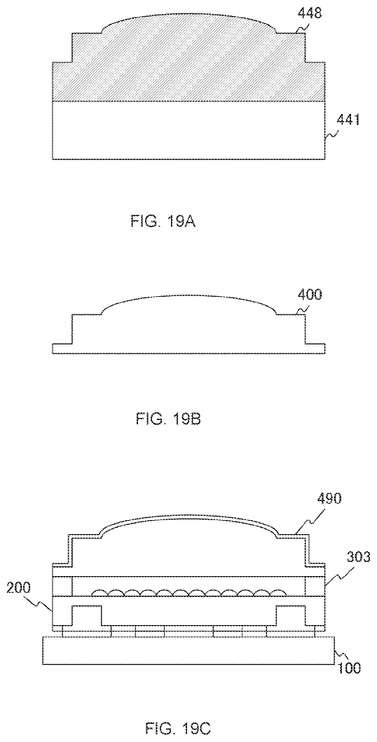

FIG. 19 is a diagram depicting a ninth example of the method for manufacturing the imaging apparatus according to the embodiment of the present technology. In the ninth example, a second example in which the cover structure 400 having a convex shape is formed using lithography and etching to manufacture an imaging apparatus having a void structure is shown.

First, as depicted in a of the drawing, the inorganic material 441 for forming the cover structure 400 is provided, and the gray tone mask 448 is formed on the surface of the inorganic material 441 by lithography to perform exposure.

Then, as depicted in b in the drawing, an unnecessary portion after exposure of the surface of the inorganic material 441 is removed by dry etching. That is, the cover structure 400 is formed as a separate body.

Thereafter, as depicted in c of the drawing, the cover structure 400 is bonded to the upper surface of the solid-state imaging element 200 via the adhesive 303, and the anti-reflection coating 490 is formed on the surface of the cover structure 400.

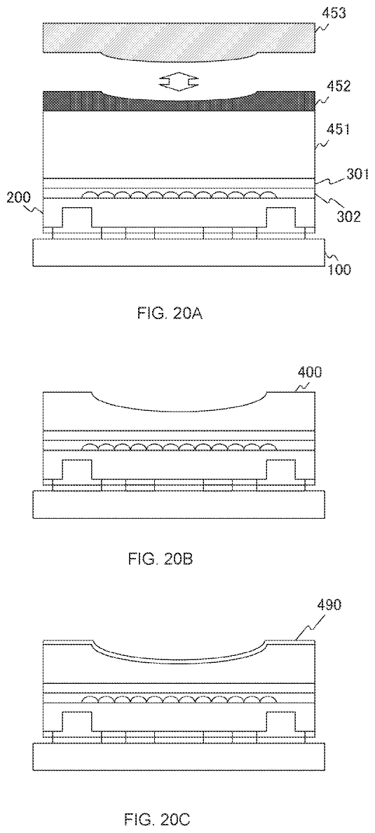

FIG. 20 is a diagram depicting a tenth example of the method for manufacturing the imaging apparatus according to the embodiment of the present technology. In the tenth example, an example in which the cover structure 400 having a concave shape is formed using imprinting and etching is depicted.

First, as depicted in a of the drawing, an inorganic material 451 for forming the cover structure 400 is provided on the upper surface of the solid-state imaging element 200 via the adhesives 302 and 301, and a resist 452 is applied to the surface thereof. Then, thermosetting or photocurable imprinting is performed by a replica mold 453.

Then, as depicted in b in the drawing, an unnecessary portion of the surface of the inorganic material 451 is removed by dry etching.

Thereafter, as depicted in c in the drawing, an anti-reflection coating 490 is formed on the surface of the cover structure 400.

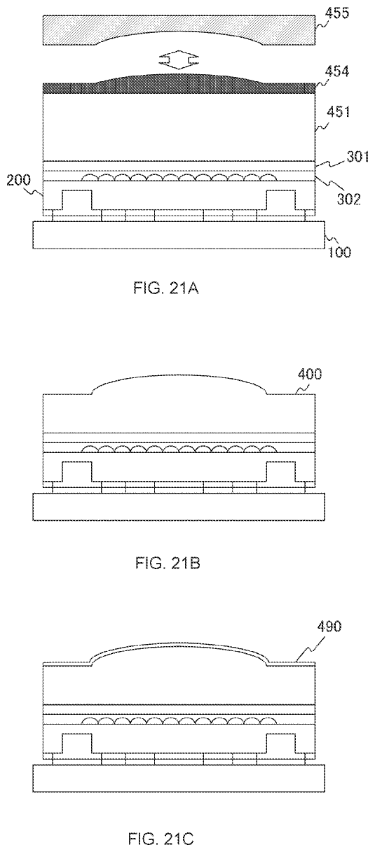

FIG. 21 is a diagram depicting an eleventh example of the method for manufacturing the imaging apparatus according to the embodiment of the present technology. In the eleventh example, an example in which the cover structure 400 having a convex shape is formed using imprinting and etching is depicted.

First, as depicted in a of the drawing, an inorganic material 451 for forming the cover structure 400 is provided on the upper surface of the solid-state imaging element 200 via the adhesives 302 and 301, and a resist 454 is applied to the surface thereof. Then, thermosetting or photocurable imprinting is performed by a replica mold 455.

Then, as depicted in b in the drawing, an unnecessary portion of the surface of the inorganic material 451 is removed by dry etching.

Thereafter, as depicted in c in the drawing, an anti-reflection coating 490 is formed on the surface of the cover structure 400.

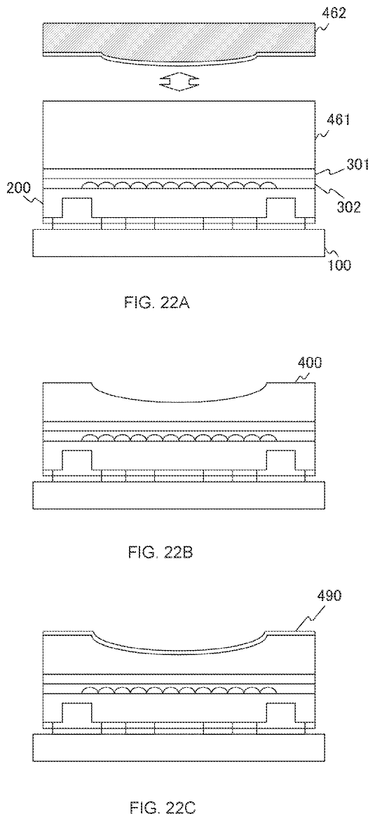

FIG. 22 is a diagram depicting a twelfth example of the method for manufacturing the imaging apparatus according to the embodiment of the present technology. In the twelfth example, an example in which the cover structure 400 having a concave shape is formed using imprinting and catalytic etching is depicted. Note that, in the twelfth example, it is assumed that the material of the cover structure 400 is a metal material such as silicon or germanium.

First, as depicted in a of the drawing, an inorganic material 461 for forming the cover structure 400 is provided on the upper surface of the solid-state imaging element 200 via the adhesives 302 and 301. Then, thermosetting or photocurable imprinting is performed by a replica mold 462.

Then, as depicted in b in the drawing, an unnecessary portion of the surface of the inorganic material 461 is removed by catalytic etching. In this catalytic etching, for example, in a case where the material of the cover structure 400 is silicon, etching is performed by repeating processing of promoting oxidation of silicon around metal fine particles and removing a silicon oxide film by a metal catalyst containing hydrogen fluoride.

Thereafter, as depicted in c in the drawing, an anti-reflection coating 490 is formed on the surface of the cover structure 400.

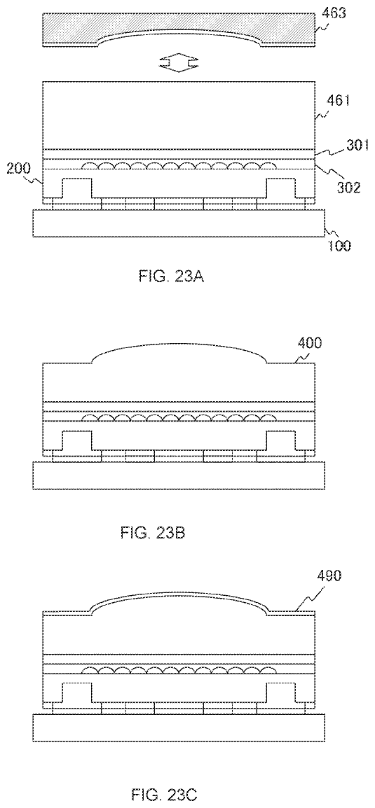

FIG. 23 is a diagram depicting a thirteenth example of the method for manufacturing the imaging apparatus according to the embodiment of the present technology. In the thirteenth example, an example in which the cover structure 400 having a convex shape is formed using imprinting and catalytic etching is depicted. Note that, in the thirteenth example, it is assumed that the material of the cover structure 400 is a metal material such as silicon or germanium.

First, as depicted in a of the drawing, an inorganic material 461 for forming the cover structure 400 is provided on the upper surface of the solid-state imaging element 200 via the adhesives 302 and 301. Then, thermosetting or photocurable imprinting is performed by a replica mold 463.

Then, as depicted in b in the drawing, an unnecessary portion of the surface of the inorganic material 461 is removed by catalytic etching.

Thereafter, as depicted in c in the drawing, an anti-reflection coating 490 is formed on the surface of the cover structure 400.

### 3. APPLICABLE EXAMPLE

The above-described embodiments are applicable to the following apparatus.

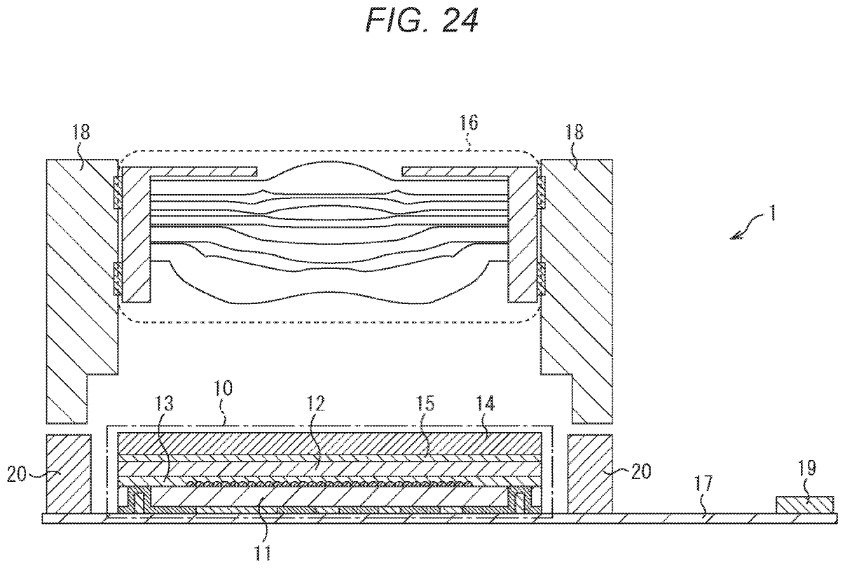

FIG. 24 is a diagram depicting a configuration example of an imaging apparatus 1 to which an embodiment of the present technology is applicable.

The imaging apparatus 1 includes a solid-state imaging element 11, a glass substrate 12, an infrared cut filter (IRCF) 14, a lens group 16, a circuit board 17, an actuator 18, a connector 19, and a spacer 20.

The solid-state imaging element 11 is an image sensor including a so-called complementary metal oxide semiconductor (CMOS), a charge coupled device (CCD), or the like, and is fixed on the circuit board 17 in an electrically connected state. The solid-state imaging element 11 includes a plurality of pixels arranged in an array, generates a pixel signal corresponding to a light amount of incident light condensed and incident from above in the figure via the lens group 16 in units of pixels, and outputs the pixel signal to the outside from the connector 19 via the circuit board 17 as an image signal.

The glass substrate 12 is provided on the upper surface portion of the solid-state imaging element 11, and is bonded by a transparent adhesive, that is, an adhesive 13 having substantially the same refractive index as the glass substrate 12.

On an upper surface portion of the glass substrate 12 in the drawing, the IRCF 14 that cuts infrared light out of incident light is provided, and is bonded by a transparent adhesive, that is, an adhesive 15 having substantially the same refractive index as the glass substrate 12. The IRCF 14 includes, for example, blue plate glass, and cuts (removes) infrared light.

That is, the solid-state imaging element 11, the glass substrate 12, and the IRCF 14 are laminated and bonded by transparent adhesives 13 and 15 to form an integrated configuration, and are connected to the circuit board 17. Note that the solid-state imaging element 11, the glass substrate 12, and the IRCF 14 surrounded by a one-dot chain line in the drawing are bonded and integrated by the adhesives 13 and 15 having substantially the same refractive index, and thus are hereinafter also simply referred to as an integrated configuration unit 10.

Furthermore, the IRCF 14 may be singulated and then attached onto the glass substrate 12 in the manufacturing processing of the solid-state imaging element 11, or a large IRCF 14 may be attached to the entire wafer-like glass substrate 12 including a plurality of solid-state imaging elements 11 and then singulated for each solid-state imaging element 11, and any method may be adopted.

The spacer 20 is formed on the circuit board 17 to surround the entire structure in which the solid-state imaging element 11, the glass substrate 12, and the IRCF 14 are integrally formed. Furthermore, the actuator 18 is provided on the spacer 20. The actuator 18 is configured in a cylindrical shape, incorporates the lens group 16 configured by laminating a plurality of lenses inside the cylinder, and is driven in the vertical direction in the drawing.

With such a configuration, the actuator 18 moves the lens group 16 in the vertical direction in the drawing (the front-rear direction with respect to the optical axis) to adjust the focus so as to form an image of the subject on the imaging surface of the solid-state imaging element 11 according to the distance to the subject (not depicted) on the upper side in the drawing, thereby implementing autofocus.

However, when the embodiment of the present technology is applied, as described above, since it is assumed that the lens and the cover of the solid-state imaging element are integrally molded with the same material, the structure is different.

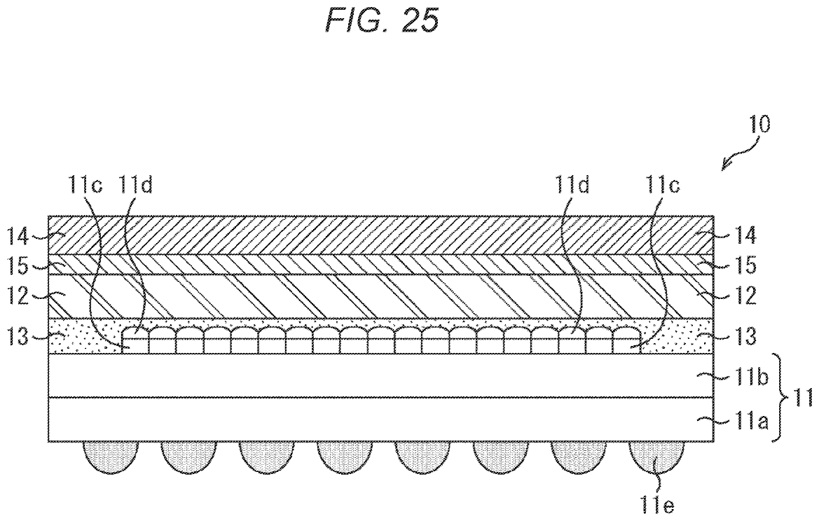

FIG. 25 is a diagram depicting a configuration example of an integrated configuration unit 10 of the imaging apparatus 1 to which the embodiment of the present technology is applicable.

The integrated configuration unit 10 is a semiconductor package in which the solid-state imaging element 11 including a laminated substrate formed by laminating a lower substrate 11a and an upper substrate 11b is packaged.

On the lower substrate 11a of the multi-layer substrate constituting the solid-state imaging element 11, a plurality of solder balls 11e as back electrodes for electrical connection with the circuit board 17 is formed.

On the upper surface of the upper substrate lib, color filters 11c of red (R), green (G), or blue (B) and on-chip lenses 11d are formed. Furthermore, the upper substrate 11b is connected to the glass substrate 12 for protecting the on-chip lenses 11d with a cavity-less structure via an adhesive 13 including a glass seal resin.

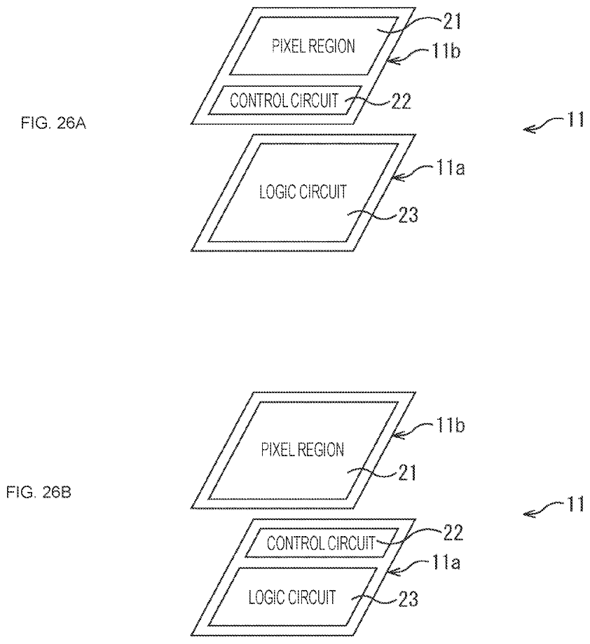

FIG. 26 is a diagram depicting an aspect example of lamination of the imaging apparatus 1 to which the embodiment of the present technology is applicable.

For example, as depicted in A of the drawing, a pixel region 21 in which pixel portions that perform photoelectric conversion are two-dimensionally arranged in an array and a control circuit 22 that controls the pixel portions are formed on the upper substrate lib, and a logic circuit 23 such as a signal processing circuit that processes a pixel signal output from the pixel portion is formed on the lower substrate 11a.

Furthermore, as depicted in B of the drawing, only the pixel region 21 may be formed on the upper substrate lib, and a control circuit 22 and a logic circuit 23 may be formed on the lower substrate 11a.

As described above, by forming and laminating the logic circuit 23 or both the control circuit 22 and the logic circuit 23 on the lower substrate 11a different from the upper substrate 11b of the pixel region 21, the size of the imaging apparatus 1 can be reduced as compared with a case where the pixel region 21, the control circuit 22, and the logic circuit 23 are arranged in the planar direction on one semiconductor substrate.

In the following description, the upper substrate 11b on which at least the pixel region 21 is formed will be referred to as a pixel sensor substrate 11b, and the lower substrate 11a on which at least the logic circuit 23 is formed will be referred to as a logic substrate 11a.

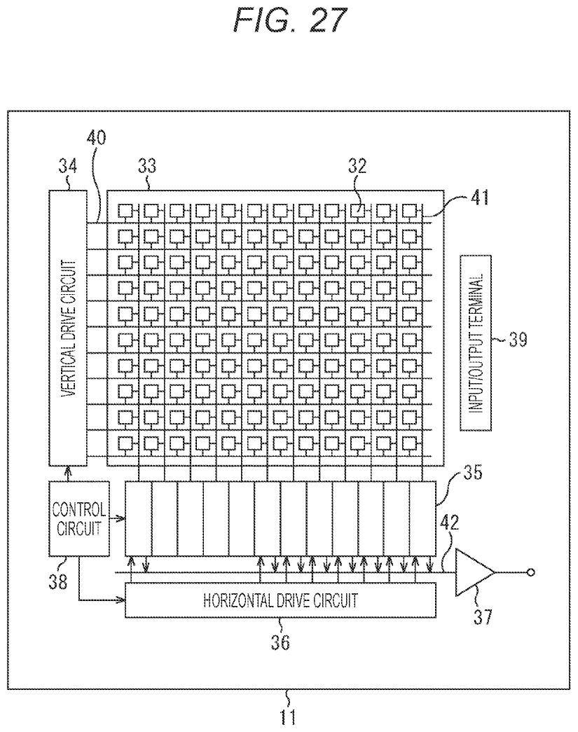

FIG. 27 is a diagram depicting a configuration example of a solid-state imaging element 11 of an imaging apparatus 1 to which an embodiment of the present technology is applicable.

The solid-state imaging element 11 includes a pixel array unit 33 in which pixels 32 are arranged in a two-dimensional array, a vertical drive circuit 34, a column signal processing circuit 35, a horizontal drive circuit 36, an output circuit 37, a control circuit 38, and an input/output terminal 39.

The pixel 32 includes a photodiode as a photoelectric conversion element and a plurality of pixel transistors. A circuit configuration example of the pixel 32 will be described later.

Furthermore, the pixels 32 may have a shared pixel structure. The pixel sharing structure includes a plurality of photodiodes, a plurality of transfer transistors, one shared floating diffusion (floating diffusion region), and one shared other pixel transistor. That is, in the shared pixel, the photodiode and the transfer transistor constituting the plurality of unit pixels are configured to share each other pixel transistor.

The control circuit 38 receives an input clock and data for instructing an operation mode and the like, and outputs data such as internal information of the solid-state imaging element 11. That is, the control circuit 38 generates a clock signal or a control signal serving as a reference of operations of the vertical drive circuit 34, the column signal processing circuit 35, the horizontal drive circuit 36, and the like on the basis of the vertical synchronization signal, the horizontal synchronization signal, and the master clock. Then, the control circuit 38 outputs the generated clock signal and control signal to the vertical drive circuit 34, the column signal processing circuit 35, the horizontal drive circuit 36, and the like.

The vertical drive circuit 34 includes, for example, a shift register, selects a predetermined pixel drive wiring 40, supplies a pulse for driving the pixels 32 to the selected pixel drive wiring 40, and drives the pixels 32 in units of rows. That is, the vertical drive circuit 34 sequentially selects and scans each pixel 32 of the pixel array unit 33 in the vertical direction in units of rows, and supplies a pixel signal based on a signal charge generated according to a received light amount in the photoelectric conversion unit of each pixel 32 to the column signal processing circuit 35 through a vertical signal line 41.

The column signal processing circuit 35 is arranged for each column of the pixels 32, and performs signal processing such as noise removal on the signals output from the pixels 32 of one row for each pixel column. For example, the column signal processing circuit 5 performs signal processing such as correlated double sampling (CDS) for removing pixel-specific fixed pattern noise and AD conversion.

The horizontal drive circuit 36 includes, for example, a shift register, sequentially selects each of the column signal processing circuits 35 by sequentially outputting horizontal scanning pulses, and causes each of the column signal processing circuits 35 to output a pixel signal to a horizontal signal line 42.

The output circuit 37 performs signal processing on the signals sequentially supplied from each of the column signal processing circuits 35 through the horizontal signal line 42, and outputs the processed signals. For example, the output circuit 37 may perform only buffering, or may perform black level adjustment, column variation correction, various digital signal processing, and the like. The input/output terminal 39 exchanges signals with the outside.

The solid-state imaging element 11 configured as described above is a CMOS image sensor called a column AD system in which column signal processing circuits 35 that perform CDS processing and AD conversion processing are arranged every pixel column.

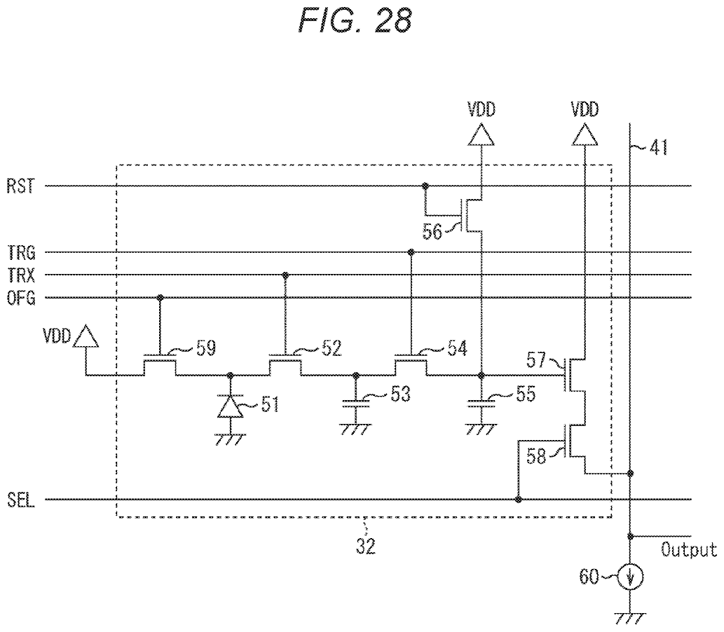

FIG. 28 is a diagram depicting an equivalent circuit of a pixel 32 of the imaging apparatus 1 to which the embodiment of the present technology is applicable. The pixel 32 illustrates a configuration that realizes an electronic global shutter function.

The pixel 32 includes a photodiode 51 as a photoelectric conversion element, a first transfer transistor 52, a memory unit (MEM) 53, a second transfer transistor 54, a floating diffusion region (FD) 55, a reset transistor 56, an amplification transistor 57, a selection transistor 58, and a discharge transistor 59.

The photodiode 51 is a photoelectric conversion unit that generates and accumulates a charge (signal charge) corresponding to the received light amount. An anode terminal of the photodiode 51 is grounded, and a cathode terminal is connected to the memory unit 53 via the first transfer transistor 52. Furthermore, the cathode terminal of the photodiode 51 is also connected to a discharge transistor 59 for discharging unnecessary charges.

When the first transfer transistor 52 is turned on by the transfer signal TRX, the first transfer transistor reads the charge generated by the photodiode 51 and transfers the charge to the memory unit 53. The memory unit 53 is a charge holding unit that temporarily holds a charge until the charge is transferred to the FD 55.

When the second transfer transistor 54 is turned on by the transfer signal TRG, the second transfer transistor 54 reads the charge held in the memory unit 53 and transfers the charge to the FD 55.

The FD 55 is a charge holding unit that holds the charge read from the memory unit 53 in order to read the charge as a signal. When reset transistor 56 is turned on by a reset signal RST, the reset transistor resets the potential of the FD 55 by discharging the charge accumulated in the FD 55 to the constant voltage source VDD.

The amplification transistor 57 outputs a pixel signal corresponding to the potential of the FD 55. That is, the amplification transistor 57 constitutes a source follower circuit with the load MOS 60 as a constant current source, and a pixel signal indicating a level corresponding to the charge accumulated in the FD 55 is output from the amplification transistor 57 to the column signal processing circuit 35 via the selection transistor 58. The load MOS 60 is disposed, for example, in the column signal processing circuit 35.

The selection transistor 58 is turned on when the pixel 32 is selected by the selection signal SEL, and outputs the pixel signal of the pixel 32 to the column signal processing circuit 35 via the vertical signal line 41.

When the discharge transistor 59 is turned on by the discharge signal OFG, the discharge transistor discharges the unnecessary charge accumulated in the photodiode 51 to the constant voltage source VDD.

The transfer signals TRX and TRG, the reset signal RST, the discharge signal OFG, and the selection signal SEL are supplied from the vertical drive circuit 34 via the pixel drive wiring 40.

The operation of the pixel 32 will be briefly described. First, before exposure is started, the discharge transistor 59 is turned on by supplying the discharge signal OFG at the high level to the discharge transistor 59, the charge accumulated in the photodiode 51 is discharged to the constant voltage source VDD, and the photodiodes 51 of all the pixels are reset.

After the photodiode 51 is reset, when the discharge transistor 59 is turned off by the discharge signal OFG at the low level, exposure is started in all the pixels of the pixel array unit 33.

When a predetermined exposure time has elapsed, the first transfer transistor 52 is turned on by the transfer signal TRX in all the pixels of the pixel array unit 33, and the charge accumulated in the photodiode 51 is transferred to the memory unit 53.

After the first transfer transistor 52 is turned off, the charges held in the memory unit 53 of each pixel 32 are sequentially read out to the column signal processing circuit 35 in units of rows. In the read operation, the second transfer transistor 54 of the pixel 32 of the read row is turned on by the transfer signal TRG, and the charge held in the memory unit 53 is transferred to the FD 55. Then, when the selection transistor 58 is turned on by the selection signal SEL, a signal indicating a level corresponding to the charge accumulated in the FD 55 is output from the amplification transistor 57 to the column signal processing circuit 35 via the selection transistor 58.

As described above, in the pixel 32 having this pixel circuit, the exposure time is set to be the same in all the pixels of the pixel array unit 33, and after the exposure is finished, the charge is temporarily held in the memory unit 53, and the global shutter type operation (imaging) of sequentially reading the charge from the memory unit 53 in units of rows is possible.

Note that the circuit configuration of the pixel 32 is not limited to the configuration depicted here, and for example, a circuit configuration that does not include the memory unit 53 and performs an operation by a so-called rolling shutter method can be adopted.

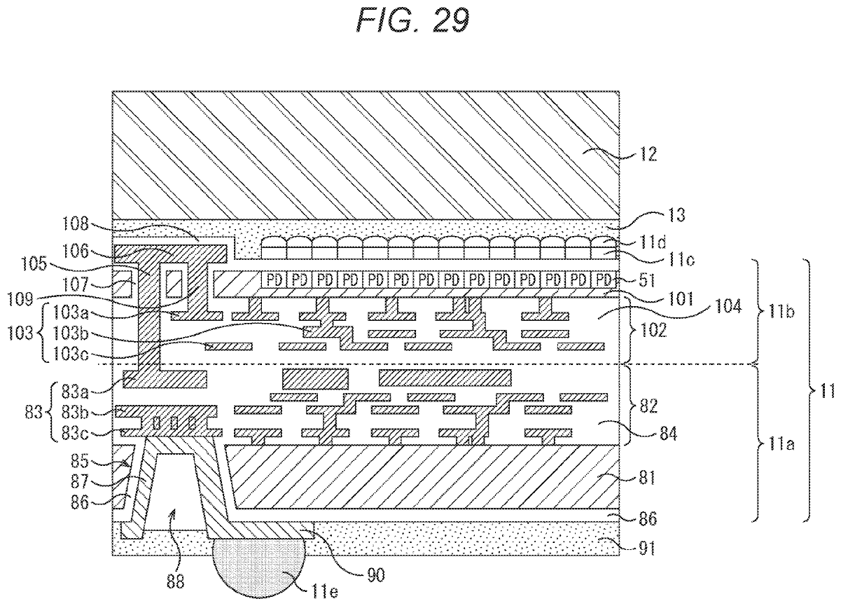

FIG. 29 is an example of a cross-sectional view of the solid-state imaging element 11 of the imaging apparatus 1 to which an embodiment of the present technology is applicable.

In the logic substrate 11a, a multilayer wiring layer 82 is formed on the upper side (pixel sensor substrate 11b side) of a semiconductor substrate 81 (hereinafter, referred to as a silicon substrate 81) including, for example, silicon (Si). The multilayer wiring layer 82 includes the control circuit 22 and the logic circuit 23.

The multilayer wiring layer 82 includes a plurality of wiring layers 83 including an uppermost wiring layer 83a closest to the pixel sensor substrate lib, an intermediate wiring layer 83b, a lowermost wiring layer 83c closest to the silicon substrate 81, and the like, and an interlayer insulating film 84 formed between the wiring layers 83.

The plurality of wiring layers 83 is formed using, for example, copper (Cu), aluminum (Al), tungsten (W), or the like, and the interlayer insulating film 84 is formed using, for example, a silicon oxide film, a silicon nitride film, or the like. In each of the plurality of wiring layers 83 and the interlayer insulating film 84, all the layers may include the same material, or two or more materials may be used depending on the layer.

A silicon through hole 85 penetrating the silicon substrate 81 is formed at a predetermined position of the silicon substrate 81, and a connection conductor 87 is embedded in an inner wall of the silicon through hole 85 via an insulating film 86 to form a through silicon via (TSV) 88. The insulating film 86 can include, for example, a SiO₂ film, a SiN film, or the like.

Note that, in the through silicon via 88, the insulating film 86 and the connection conductor 87 are formed along the inner wall surface, and the inside of the through silicon via 85 is hollow. However, depending on the inner diameter, the entire inside of the through silicon via 85 may be filled with the connection conductor 87. In other words, the inside of the through hole may be embedded with a conductor, or a part of the through hole may be a cavity. The same applies to a through chip via (TCV) 105 and the like as described later.

The connection conductor 87 of the through silicon via 88 is connected to a rewiring 90 formed on the lower surface side of the silicon substrate 81, and the rewiring 90 is connected to the solder ball 11e. The connection conductor 87 and the rewiring 90 can include, for example, copper (Cu), tungsten (W), tungsten (W), polysilicon, or the like.

Furthermore, on the lower surface side of the silicon substrate 81, a solder mask (solder resist) 91 is formed so as to cover the rewiring 90 and the insulating film 86 except for the region where the solder balls 11e are formed.

On the other hand, in the pixel sensor substrate lib, a multilayer wiring layer 102 is formed on the lower side (logic substrate 11a side) of a semiconductor substrate 101 (hereinafter, referred to as a silicon substrate 101) including silicon (Si). The multilayer wiring layer 102 includes a pixel circuit of the pixel region 21.

The multilayer wiring layer 102 includes a plurality of wiring layers 103 including an uppermost wiring layer 103a closest to the silicon substrate 101, an intermediate wiring layer 103b, a lowermost wiring layer 103c closest to the logic substrate 11a, and the like, and an interlayer insulating film 104 formed between the wiring layers 103.

As the material used as the plurality of wiring layers 103 and the interlayer insulating film 104, the same type of material as the material of the wiring layer 83 and the interlayer insulating film 84 described above can be adopted. Furthermore, the plurality of wiring layers 103 and the interlayer insulating film 104 may be formed by using one or two or more materials, which is similar to the wiring layers 83 and the interlayer insulating film 84 described above.

Note that, in this example, the multilayer wiring layer 102 of the pixel sensor substrate 11b includes the three wiring layers 103, and the multilayer wiring layer 82 of the logic substrate 11a includes the four wiring layers 83. However, the total number of wiring layers is not limited thereto, and any number of wiring layers can be formed.

In the silicon substrate 101, a photodiode 51 formed by a PN junction is formed every pixel 32.

Furthermore, although not depicted, a plurality of pixel transistors such as the first transfer transistor 52 and the second transfer transistor 54, a memory unit (MEM) 53, and the like are also formed in the multilayer wiring layer 102 and the silicon substrate 101.

At a predetermined position of the silicon substrate 101 where the color filter 11c and the on-chip lens 11d are not formed, a through silicon via 109 connected to the wiring layer 103a of the pixel sensor substrate 11b and the through chip via 105 connected to the wiring layer 83a of the logic substrate 11a are formed.

The through chip via 105 and the through silicon via 109 are connected by a connection wiring 106 formed on the upper surface of the silicon substrate 101. Furthermore, an insulating film 107 is formed between each of the through silicon via 109 and the through chip via 105 and the silicon substrate 101. Moreover, on the upper surface of the silicon substrate 101, the color filter 11c and the on-chip lens 11d are formed via a planarization film (insulating film) 108.

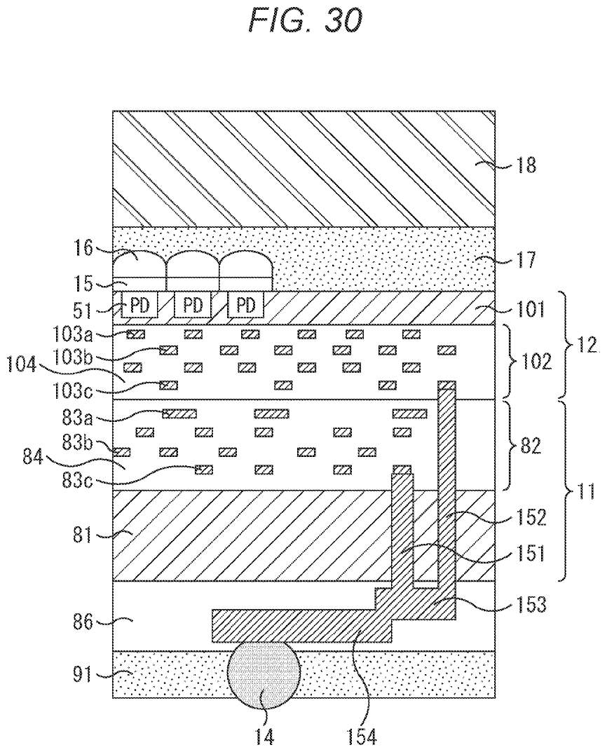

FIG. 30 is an example of a cross-sectional view of another solid-state imaging element of the imaging apparatus to which an embodiment of the present technology is applicable.

In this example, the logic substrate 11 and the pixel sensor substrate 12 are connected on the logic substrate 11 side on the lower side using two through electrodes of a through silicon via 151 and a through chip via 152. That is, a laminated structure of the logic substrate 11 and the pixel sensor substrate 12 is adopted.

More specifically, a through silicon via 151 connected to the wiring layer 83c of the logic substrate 11 and the through chip via 152 connected to the wiring layer 103c of the pixel sensor substrate 12 are formed at a predetermined position of the silicon substrate 81 on the logic substrate 11 side. Note that the through silicon via 151 and the through chip via 152 are insulated from the silicon substrate 81 by an insulating film (not depicted).

The through silicon via 151 and the through chip via 152 are connected by a connection wiring 153 formed on the lower surface of the silicon substrate 81. The connection wiring 153 is also connected to the rewiring 154 connected to the solder ball 14.

### 4. APPLICATION EXAMPLE

For example, the above-described imaging apparatus can be applied to various types of electronic equipment such as an imaging apparatus such as a digital still camera or a digital video camera, a mobile phone having an imaging function, or another device having an imaging function.

[Electronic Equipment]

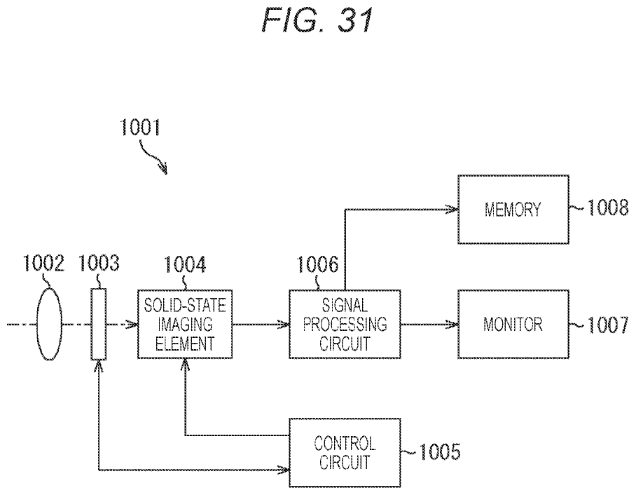

FIG. 31 is a block diagram depicting a configuration example of an imaging apparatus 1001 as electronic equipment to which the present technology is applicable.

The imaging apparatus 1001 includes an optical system 1002, a shutter device 1003, a solid-state imaging element 1004, a drive circuit 1005, a signal processing circuit 1006, a monitor 1007, and a memory 1008, and can capture a still image and a moving image.

The optical system 1002 includes one or a plurality of lenses, guides light (incident light) from a subject to the solid-state imaging element 1004, and forms an image on a light receiving surface of the solid-state imaging element 1004.

The shutter device 1003 is arranged between the optical system 1002 and the solid-state imaging element 1004, and controls a light irradiation period and a light shielding period with respect to the solid-state imaging element 1004 according to the control of the drive circuit 1005.

The solid-state imaging element 1004 includes a package including the above-described solid-state imaging element. The solid-state imaging element 1004 accumulates signal charges for a certain period according to light formed on the light receiving surface via the optical system 1002 and the shutter device 1003. The signal charge accumulated in the solid-state imaging element 1004 is transferred in accordance with a drive signal (timing signal) supplied from the drive circuit 1005.

The drive circuit 1005 outputs a drive signal for controlling a transfer operation of the solid-state imaging element 1004 and a shutter operation of the shutter device 1003 to drive the solid-state imaging element 1004 and the shutter device 1003.

The signal processing circuit 1006 performs various types of signal processing on the signal charge output from the solid-state imaging element 1004. An image (image data) obtained by performing the signal processing by the signal processing circuit 1006 is supplied to and displayed on the monitor 1007, or supplied to and stored (recorded) in the memory 1008.

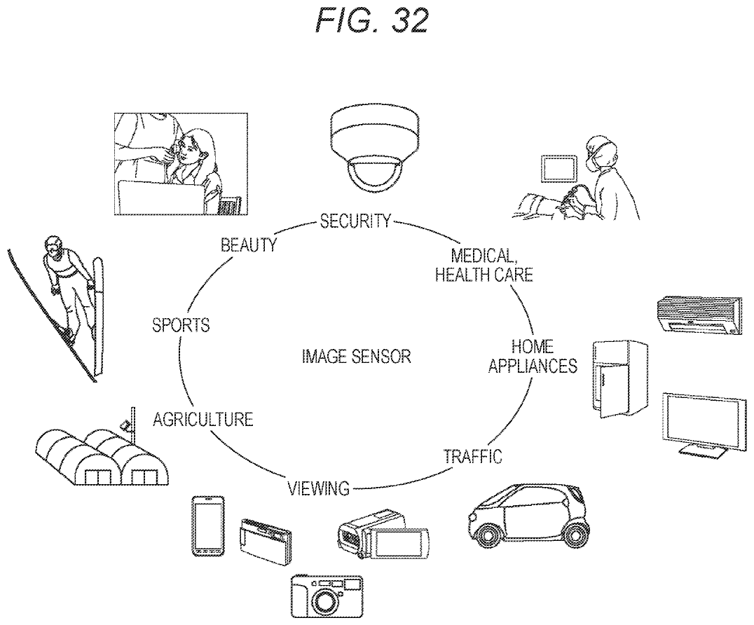

FIG. 32 is a diagram depicting an application example of an imaging apparatus as electronic equipment to which the present technology is applicable.

The imaging apparatus according to the embodiment of the present technology can be used, for example, in various cases of sensing light such as visible light, infrared light, ultraviolet light, and X-rays as follows.

For example, an apparatus that captures an image to be used for viewing, such as a digital camera or a portable device with a camera function, is assumed. Furthermore, for safe driving such as automatic stop, recognition of a driver's condition, and the like, devices used for traffic are assumed, such as an in-vehicle sensor that captures images of the front, rear, surroundings, inside, and the like of an automobile, a monitoring camera that monitors traveling vehicles and roads, and a distance measuring sensor that measures a distance between vehicles and the like. Furthermore, in order to capture an image of a gesture of a user and operate equipment according to the gesture, an apparatus provided for home appliances such as a TV, a refrigerator, and an air conditioner is assumed. Furthermore, an apparatus provided for medical care or health care, such as an endoscope or a device that performs angiography by receiving infrared light, is assumed. Furthermore, an apparatus used for security, such as a monitoring camera for crime prevention and a camera for person authentication, is assumed. Furthermore, an apparatus used for beauty care, such as a skin measuring instrument for imaging the skin or a microscope for imaging the scalp, is assumed. Furthermore, an apparatus used for sports, such as an action camera and a wearable camera for sports and the like, is assumed. Furthermore, an apparatus used for agriculture, such as a camera for monitoring the conditions of fields and crops, is assumed.

[Endoscopic Surgery System]

The technology according to the present disclosure can be applied to various products. For example, the technology according to the present disclosure may be applied to an endoscopic surgery system.

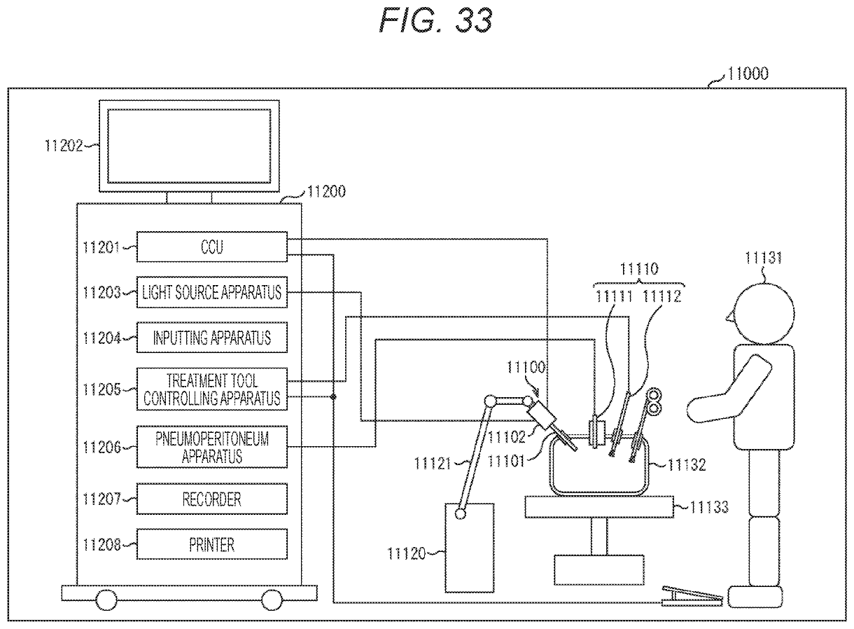

FIG. 33 is a view depicting an example of a schematic configuration of an endoscopic surgery system to which the technology according to an embodiment of the present disclosure can be applied.

In FIG. 33, a state is depicted in which a surgeon (medical doctor) 11131 is using an endoscopic surgery system 11000 to perform surgery for a patient 11132 on a patient bed 11133. As depicted, the endoscopic surgery system 11000 includes an endoscope 11100, other surgical tools 11110 such as a pneumoperitoneum tube 11111 and an energy device 11112, a supporting arm apparatus 11120 which supports the endoscope 11100 thereon, and a cart 11200 on which various apparatus for endoscopic surgery are mounted.

The endoscope 11100 includes a lens barrel 11101 having a region of a predetermined length from a distal end thereof to be inserted into a body cavity of the patient 11132, and a camera head 11102 connected to a proximal end of the lens barrel 11101. In the example depicted, the endoscope 11100 is depicted which includes as a rigid endoscope having the lens barrel 11101 of the hard type. However, the endoscope 11100 may otherwise be included as a flexible endoscope having the lens barrel 11101 of the flexible type.

The lens barrel 11101 has, at a distal end thereof, an opening in which an objective lens is fitted. A light source apparatus 11203 is connected to the endoscope 11100 such that light generated by the light source apparatus 11203 is introduced to a distal end of the lens barrel 11101 by a light guide extending in the inside of the lens barrel 11101 and is irradiated toward an observation target in a body cavity of the patient 11132 through the objective lens. It is to be noted that the endoscope 11100 may be a forward-viewing endoscope or may be an oblique-viewing endoscope or a side-viewing endoscope.

An optical system and an image pickup element are provided in the inside of the camera head 11102 such that reflected light (observation light) from the observation target is condensed on the image pickup element by the optical system. The observation light is photo-electrically converted by the image pickup element to generate an electric signal corresponding to the observation light, namely, an image signal corresponding to an observation image. The image signal is transmitted as RAW data to a CCU 11201.

The CCU 11201 includes a central processing unit (CPU), a graphics processing unit (GPU) or the like and integrally controls operation of the endoscope 11100 and a display apparatus 11202. Further, the CCU 11201 receives an image signal from the camera head 11102 and performs, for the image signal, various image processes for displaying an image based on the image signal such as, for example, a development process (demosaic process).

The display apparatus 11202 displays thereon an image based on an image signal, for which the image processes have been performed by the CCU 11201, under the control of the CCU 11201.

The light source apparatus 11203 includes a light source such as, for example, a light emitting diode (LED) and supplies irradiation light upon imaging of a surgical region to the endoscope 11100.

An inputting apparatus 11204 is an input interface for the endoscopic surgery system 11000. A user can perform inputting of various kinds of information or instruction inputting to the endoscopic surgery system 11000 through the inputting apparatus 11204. For example, the user would input an instruction or a like to change an image pickup condition (type of irradiation light, magnification, focal distance or the like) by the endoscope 11100.

A treatment tool controlling apparatus 11205 controls driving of the energy device 11112 for cautery or incision of a tissue, sealing of a blood vessel or the like. A pneumoperitoneum apparatus 11206 feeds gas into a body cavity of the patient 11132 through the pneumoperitoneum tube 11111 to inflate the body cavity in order to secure the field of view of the endoscope 11100 and secure the working space for the surgeon. A recorder 11207 is an apparatus capable of recording various kinds of information relating to surgery. A printer 11208 is an apparatus capable of printing various kinds of information relating to surgery in various forms such as a text, an image or a graph.

It is to be noted that the light source apparatus 11203 which supplies irradiation light when a surgical region is to be imaged to the endoscope 11100 may include a white light source which includes, for example, an LED, a laser light source or a combination of them. Where a white light source includes a combination of red, green, and blue (RGB) laser light sources, since the output intensity and the output timing can be controlled with a high degree of accuracy for each color (each wavelength), adjustment of the white balance of a picked up image can be performed by the light source apparatus 11203. Further, in this case, if laser beams from the respective RGB laser light sources are irradiated time-divisionally on an observation target and driving of the image pickup elements of the camera head 11102 are controlled in synchronism with the irradiation timings. Then images individually corresponding to the R, G and B colors can be also picked up time-divisionally. According to this method, a color image can be obtained even if color filters are not provided for the image pickup element.

Further, the light source apparatus 11203 may be controlled such that the intensity of light to be outputted is changed for each predetermined time. By controlling driving of the image pickup element of the camera head 11102 in synchronism with the timing of the change of the intensity of light to acquire images time-divisionally and synthesizing the images, an image of a high dynamic range free from underexposed blocked up shadows and overexposed highlights can be created.

Further, the light source apparatus 11203 may be configured to supply light of a predetermined wavelength band ready for special light observation. In special light observation, for example, by utilizing the wavelength dependency of absorption of light in a body tissue to irradiate light of a narrow band in comparison with irradiation light upon ordinary observation (namely, white light), narrow band observation (narrow band imaging) of imaging a predetermined tissue such as a blood vessel of a superficial portion of the mucous membrane or the like in a high contrast is performed. Alternatively, in special light observation, fluorescent observation for obtaining an image from fluorescent light generated by irradiation of excitation light may be performed. In fluorescent observation, it is possible to perform observation of fluorescent light from a body tissue by irradiating excitation light on the body tissue (autofluorescence observation) or to obtain a fluorescent light image by locally injecting a reagent such as indocyanine green (ICG) into a body tissue and irradiating excitation light corresponding to a fluorescent light wavelength of the reagent upon the body tissue. The light source apparatus 11203 can be configured to supply such narrow-band light and/or excitation light suitable for special light observation as described above.

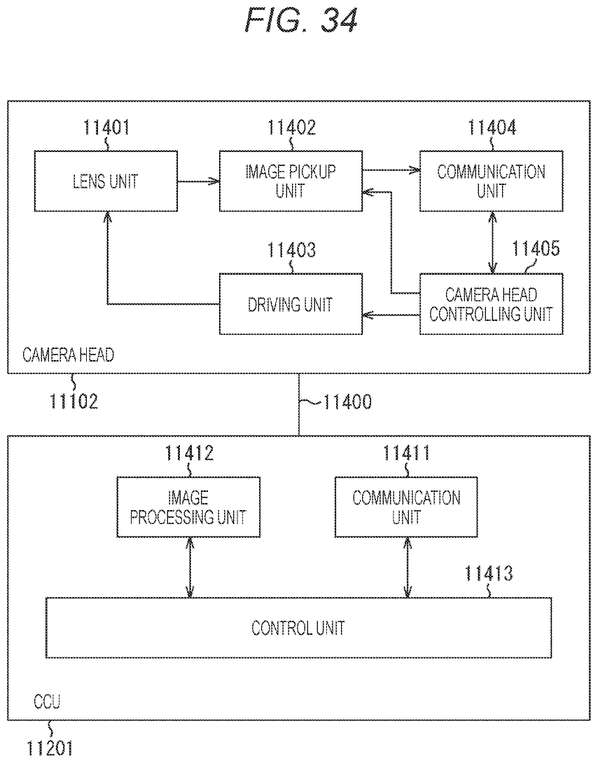

FIG. 34 is a block diagram depicting an example of a functional configuration of the camera head 11102 and the CCU 11201 depicted in FIG. 33.

The camera head 11102 includes a lens unit 11401, an image pickup unit 11402, a driving unit 11403, a communication unit 11404 and a camera head controlling unit 11405. The CCU 11201 includes a communication unit 11411, an image processing unit 11412 and a control unit 11413. The camera head 11102 and the CCU 11201 are connected for communication to each other by a transmission cable 11400.

The lens unit 11401 is an optical system, provided at a connecting location to the lens barrel 11101. Observation light taken in from a distal end of the lens barrel 11101 is guided to the camera head 11102 and introduced into the lens unit 11401. The lens unit 11401 includes a combination of a plurality of lenses including a zoom lens and a focusing lens.

The number of image pickup elements which is included by the image pickup unit 11402 may be one (single-plate type) or a plural number (multi-plate type). Where the image pickup unit 11402 is configured as that of the multi-plate type, for example, image signals corresponding to respective R, G and B are generated by the image pickup elements, and the image signals may be synthesized to obtain a color image. The image pickup unit 11402 may also be configured so as to have a pair of image pickup elements for acquiring respective image signals for the right eye and the left eye ready for three dimensional (3D) display. If 3D display is performed, then the depth of a living body tissue in a surgical region can be comprehended more accurately by the surgeon 11131. It is to be noted that, where the image pickup unit 11402 is configured as that of stereoscopic type, a plurality of systems of lens units 11401 are provided corresponding to the individual image pickup elements.

Further, the image pickup unit 11402 may not necessarily be provided on the camera head 11102. For example, the image pickup unit 11402 may be provided immediately behind the objective lens in the inside of the lens barrel 11101.

The driving unit 11403 includes an actuator and moves the zoom lens and the focusing lens of the lens unit 11401 by a predetermined distance along an optical axis under the control of the camera head controlling unit 11405. Consequently, the magnification and the focal point of a picked up image by the image pickup unit 11402 can be adjusted suitably.

The communication unit 11404 includes a communication apparatus for transmitting and receiving various kinds of information to and from the CCU 11201. The communication unit 11404 transmits an image signal acquired from the image pickup unit 11402 as RAW data to the CCU 11201 through the transmission cable 11400.

In addition, the communication unit 11404 receives a control signal for controlling driving of the camera head 11102 from the CCU 11201 and supplies the control signal to the camera head controlling unit 11405. The control signal includes information relating to image pickup conditions such as, for example, information that a frame rate of a picked up image is designated, information that an exposure value upon image picking up is designated and/or information that a magnification and a focal point of a picked up image are designated.

It is to be noted that the image pickup conditions such as the frame rate, exposure value, magnification or focal point may be designated by the user or may be set automatically by the control unit 11413 of the CCU 11201 on the basis of an acquired image signal. In the latter case, an auto exposure (AE) function, an auto focus (AF) function and an auto white balance (AWB) function are incorporated in the endoscope 11100.

The camera head controlling unit 11405 controls driving of the camera head 11102 on the basis of a control signal from the CCU 11201 received through the communication unit 11404.

The communication unit 11411 includes a communication apparatus for transmitting and receiving various kinds of information to and from the camera head 11102. The communication unit 11411 receives an image signal transmitted thereto from the camera head 11102 through the transmission cable 11400.

Further, the communication unit 11411 transmits a control signal for controlling driving of the camera head 11102 to the camera head 11102. The image signal and the control signal can be transmitted by electrical communication, optical communication or the like.

The image processing unit 11412 performs various image processes for an image signal in the form of RAW data transmitted thereto from the camera head 11102.

The control unit 11413 performs various kinds of control relating to image picking up of a surgical region or the like by the endoscope 11100 and display of a picked up image obtained by image picking up of the surgical region or the like. For example, the control unit 11413 creates a control signal for controlling driving of the camera head 11102.

Further, the control unit 11413 controls, on the basis of an image signal for which image processes have been performed by the image processing unit 11412, the display apparatus 11202 to display a picked up image in which the surgical region or the like is imaged. Thereupon, the control unit 11413 may recognize various objects in the picked up image using various image recognition technologies. For example, the control unit 11413 can recognize a surgical tool such as forceps, a particular living body region, bleeding, mist when the energy device 11112 is used and so forth by detecting the shape, color and so forth of edges of objects included in a picked up image. The control unit 11413 may cause, when it controls the display apparatus 11202 to display a picked up image, various kinds of surgery supporting information to be displayed in an overlapping manner with an image of the surgical region using a result of the recognition. Where surgery supporting information is displayed in an overlapping manner and presented to the surgeon 11131, the burden on the surgeon 11131 can be reduced and the surgeon 11131 can proceed with the surgery with certainty.

The transmission cable 11400 which connects the camera head 11102 and the CCU 11201 to each other is an electric signal cable ready for communication of an electric signal, an optical fiber ready for optical communication or a composite cable ready for both of electrical and optical communications.

Here, while, in the example depicted, communication is performed by wired communication using the transmission cable 11400, the communication between the camera head 11102 and the CCU 11201 may be performed by wireless communication.

An example of the endoscopic surgery system to which the technology according to the present disclosure can be applied has been described above. The technology according to the present disclosure can be applied to, for example, the endoscope 11100, the image pickup unit 11402 of the camera head 11102, and the like among the above-described configurations.

Note that, here, the endoscopic surgery system has been described as an example, but the technology according to the present disclosure may be applied to, for example, a microscopic surgery system or the like.

[Mobile Body Control System]

The technology (the present technology) according to the present disclosure can be applied to various products. For example, the technology according to the present disclosure may be realized as a device mounted on any type of a mobile body such as an automobile, an electric vehicle, a hybrid electric vehicle, a motorcycle, a bicycle, a personal mobility, an airplane, a drone, a ship, and a robot.

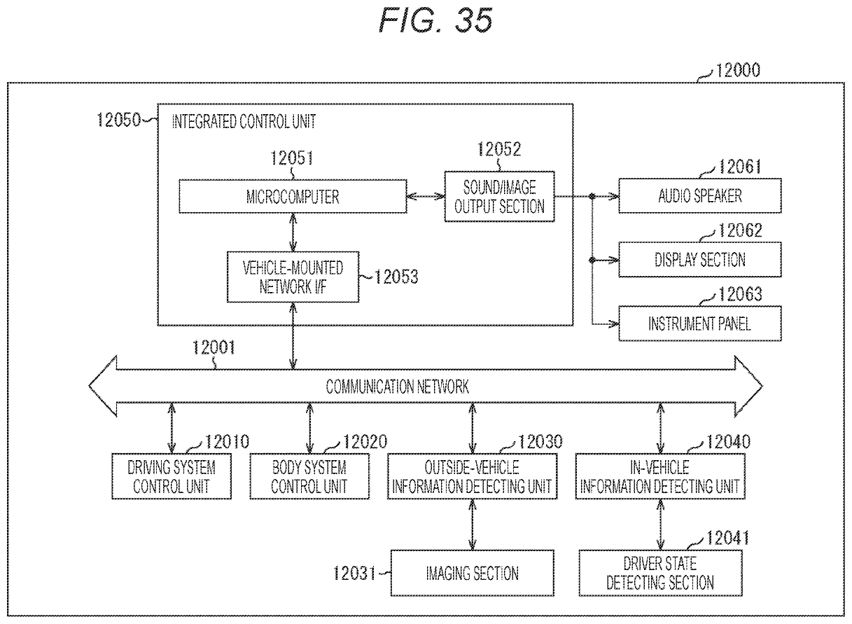

FIG. 35 is a block diagram depicting an example of schematic configuration of a vehicle control system as an example of a mobile body control system to which the technology according to the present disclosure can be applied.

The vehicle control system 12000 includes a plurality of electronic control units connected to each other via a communication network 12001. In the example depicted in FIG. 35, the vehicle control system 12000 includes a driving system control unit 12010, a body system control unit 12020, an outside-vehicle information detecting unit 12030, an in-vehicle information detecting unit 12040, and an integrated control unit 12050. In addition, a microcomputer 12051, a sound/image output section 12052, and a vehicle-mounted network interface (I/F) 12053 are illustrated as a functional configuration of the integrated control unit 12050.

The driving system control unit 12010 controls the operation of devices related to the driving system of the vehicle in accordance with various kinds of programs. For example, the driving system control unit 12010 functions as a control device for a driving force generating device for generating the driving force of the vehicle, such as an internal combustion engine, a driving motor, or the like, a driving force transmitting mechanism for transmitting the driving force to wheels, a steering mechanism for adjusting the steering angle of the vehicle, a braking device for generating the braking force of the vehicle, and the like.

The body system control unit 12020 controls the operation of various kinds of devices provided to a vehicle body in accordance with various kinds of programs. For example, the body system control unit 12020 functions as a control device for a keyless entry system, a smart key system, a power window device, or various kinds of lamps such as a headlamp, a backup lamp, a brake lamp, a turn signal, a fog lamp, or the like. In this case, radio waves transmitted from a mobile device as an alternative to a key or signals of various kinds of switches can be input to the body system control unit 12020. The body system control unit 12020 receives these input radio waves or signals, and controls a door lock device, the power window device, the lamps, or the like of the vehicle.

The outside-vehicle information detecting unit 12030 detects information about the outside of the vehicle including the vehicle control system 12000. For example, the outside-vehicle information detecting unit 12030 is connected with an imaging section 12031. The outside-vehicle information detecting unit 12030 makes the imaging section 12031 image an image of the outside of the vehicle, and receives the imaged image. On the basis of the received image, the outside-vehicle information detecting unit 12030 may perform processing of detecting an object such as a human, a vehicle, an obstacle, a sign, a character on a road surface, or the like, or processing of detecting a distance thereto.

The imaging section 12031 is an optical sensor that receives light, and which outputs an electric signal corresponding to a received light amount of the light. The imaging section 12031 can output the electric signal as an image, or can output the electric signal as information about a measured distance. In addition, the light received by the imaging section 12031 may be visible light, or may be invisible light such as infrared rays or the like.

The in-vehicle information detecting unit 12040 detects information about the inside of the vehicle. The in-vehicle information detecting unit 12040 is, for example, connected with a driver state detecting section 12041 that detects the state of a driver. The driver state detecting section 12041, for example, includes a camera that images the driver. On the basis of detection information input from the driver state detecting section 12041, the in-vehicle information detecting unit 12040 may calculate a degree of fatigue of the driver or a degree of concentration of the driver, or may determine whether the driver is dozing.

The microcomputer 12051 can calculate a control target value for the driving force generating device, the steering mechanism, or the braking device on the basis of the information about the inside or outside of the vehicle which information is obtained by the outside-vehicle information detecting unit 12030 or the in-vehicle information detecting unit 12040, and output a control command to the driving system control unit 12010. For example, the microcomputer 12051 can perform cooperative control intended to implement functions of an advanced driver assistance system (ADAS) which functions include collision avoidance or shock mitigation for the vehicle, following driving based on a following distance, vehicle speed maintaining driving, a warning of collision of the vehicle, a warning of deviation of the vehicle from a lane, or the like.

In addition, the microcomputer 12051 can perform cooperative control intended for automated driving, which makes the vehicle to travel automatedly without depending on the operation of the driver, or the like, by controlling the driving force generating device, the steering mechanism, the braking device, or the like on the basis of the information about the outside or inside of the vehicle which information is obtained by the outside-vehicle information detecting unit 12030 or the in-vehicle information detecting unit 12040.

In addition, the microcomputer 12051 can output a control command to the body system control unit 12030 on the basis of the information about the outside of the vehicle which information is obtained by the outside-vehicle information detecting unit 12030. For example, the microcomputer 12051 can perform cooperative control intended to prevent a glare by controlling the headlamp so as to change from a high beam to a low beam, for example, in accordance with the position of a preceding vehicle or an oncoming vehicle detected by the outside-vehicle information detecting unit 12030.

The sound/image output section 12052 transmits an output signal of at least one of a sound and an image to an output device capable of visually or auditorily notifying information to an occupant of the vehicle or the outside of the vehicle. In the example of FIG. 35, an audio speaker 12061, a display section 12062, and an instrument panel 12063 are depicted as the output device. The display section 12062 may, for example, include at least one of an on-board display and a head-up display.

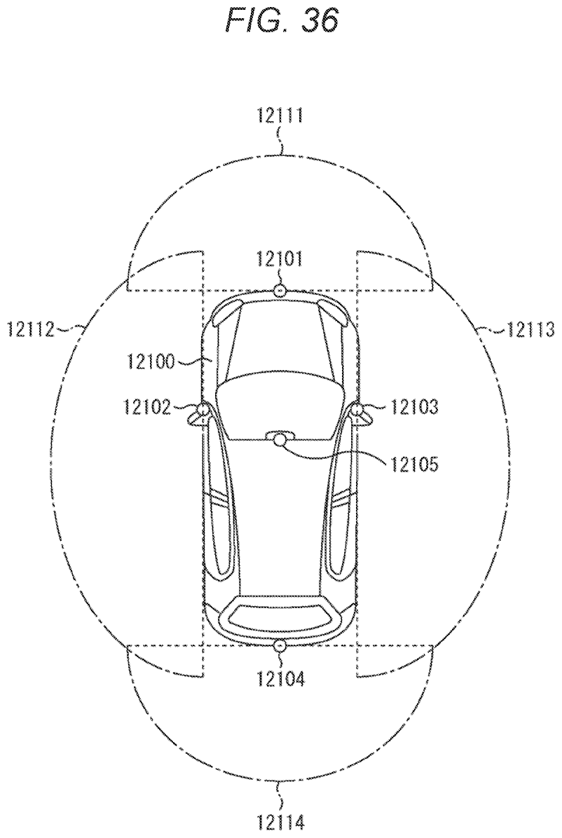

FIG. 36 is a diagram depicting an example of the installation position of the imaging section 12031.

In FIG. 36, the imaging section 12031 includes imaging sections 12101, 12102, 12103, 12104, and 12105.

The imaging sections 12101, 12102, 12103, 12104, and 12105 are, for example, disposed at positions on a front nose, sideview mirrors, a rear bumper, and a back door of the vehicle 12100 as well as a position on an upper portion of a windshield within the interior of the vehicle. The imaging section 12101 provided to the front nose and the imaging section 12105 provided to the upper portion of the windshield within the interior of the vehicle obtain mainly an image of the front of the vehicle 12100. The imaging sections 12102 and 12103 provided to the sideview mirrors obtain mainly an image of the sides of the vehicle 12100. The imaging section 12104 provided to the rear bumper or the back door obtains mainly an image of the rear of the vehicle 12100. The imaging section 12105 provided to the upper portion of the windshield within the interior of the vehicle is used mainly to detect a preceding vehicle, a pedestrian, an obstacle, a signal, a traffic sign, a lane, or the like.

Incidentally, FIG. 36 depicts an example of photographing ranges of the imaging sections 12101 to 12104. An imaging range 12111 represents the imaging range of the imaging section 12101 provided to the front nose. Imaging ranges 12112 and 12113 respectively represent the imaging ranges of the imaging sections 12102 and 12103 provided to the sideview mirrors. An imaging range 12114 represents the imaging range of the imaging section 12104 provided to the rear bumper or the back door. A bird's-eye image of the vehicle 12100 as viewed from above is obtained by superimposing image data imaged by the imaging sections 12101 to 12104, for example.

At least one of the imaging sections 12101 to 12104 may have a function of obtaining distance information. For example, at least one of the imaging sections 12101 to 12104 may be a stereo camera constituted of a plurality of imaging elements, or may be an imaging element having pixels for phase difference detection.

For example, the microcomputer 12051 can determine a distance to each three-dimensional object within the imaging ranges 12111 to 12114 and a temporal change in the distance (relative speed with respect to the vehicle 12100) on the basis of the distance information obtained from the imaging sections 12101 to 12104, and thereby extract, as a preceding vehicle, a nearest three-dimensional object in particular that is present on a traveling path of the vehicle 12100 and which travels in substantially the same direction as the vehicle 12100 at a predetermined speed (for example, equal to or more than 0 km/hour). Further, the microcomputer 12051 can set a following distance to be maintained in front of a preceding vehicle in advance, and perform automatic brake control (including following stop control), automatic acceleration control (including following start control), or the like. It is thus possible to perform cooperative control intended for automated driving that makes the vehicle travel automatedly without depending on the operation of the driver or the like.

For example, the microcomputer 12051 can classify three-dimensional object data on three-dimensional objects into three-dimensional object data of a two-wheeled vehicle, a standard-sized vehicle, a large-sized vehicle, a pedestrian, a utility pole, and other three-dimensional objects on the basis of the distance information obtained from the imaging sections 12101 to 12104, extract the classified three-dimensional object data, and use the extracted three-dimensional object data for automatic avoidance of an obstacle. For example, the microcomputer 12051 identifies obstacles around the vehicle 12100 as obstacles that the driver of the vehicle 12100 can recognize visually and obstacles that are difficult for the driver of the vehicle 12100 to recognize visually. Then, the microcomputer 12051 determines a collision risk indicating a risk of collision with each obstacle. In a situation in which the collision risk is equal to or higher than a set value and there is thus a possibility of collision, the microcomputer 12051 outputs a warning to the driver via the audio speaker 12061 or the display section 12062, and performs forced deceleration or avoidance steering via the driving system control unit 12010. The microcomputer 12051 can thereby assist in driving to avoid collision.

At least one of the imaging sections 12101 to 12104 may be an infrared camera that detects infrared rays. The microcomputer 12051 can, for example, recognize a pedestrian by determining whether or not there is a pedestrian in imaged images of the imaging sections 12101 to 12104. Such recognition of a pedestrian is, for example, performed by a procedure of extracting characteristic points in the imaged images of the imaging sections 12101 to 12104 as infrared cameras and a procedure of determining whether or not it is the pedestrian by performing pattern matching processing on a series of characteristic points representing the contour of the object. When the microcomputer 12051 determines that there is a pedestrian in the imaged images of the imaging sections 12101 to 12104, and thus recognizes the pedestrian, the sound/image output section 12052 controls the display section 12062 so that a square contour line for emphasis is displayed so as to be superimposed on the recognized pedestrian. The sound/image output section 12052 may also control the display section 12062 so that an icon or the like representing the pedestrian is displayed at a desired position.

An example of the vehicle control system to which the technology according to the present disclosure can be applied has been described above. The technology according to the present disclosure can be applied to, for example, the imaging section 12031 and the like among the configurations described above.

Note that the above-described embodiment illustrates an example for embodying the present technology, and the matters in the embodiment and the invention specifying matters in the claims have a correspondence relationship. Similarly, the matters specifying the invention in the claims and the matters in the embodiments of the present technology denoted by the same names as the matters specifying the invention have a correspondence relationship. However, the present technology is not limited to the embodiments, and can be embodied by making various modifications to the embodiments without departing from the gist thereof.

Furthermore, the processing procedure described in the above-described embodiment may be regarded as a method including these series of procedures, and may be regarded as a program for causing a computer to execute these series of procedures or a recording medium storing the program. As this recording medium, for example, a compact disc (CD), a MiniDisc (MD), a digital versatile disc (DVD), a memory card, a Blu-ray (registered trademark) disc, or the like can be used.

Note that the effects described in the present specification are merely examples and are not limited, and other effects may be provided.

Note that the present technology can also adopt the following configurations.

(1) An imaging apparatus including:

a solid-state imaging element configured to generate a pixel signal by photoelectric conversion according to a light amount of incident light; and

a cover structure having a non-flat surface for focusing the incident light on a light receiving surface of the solid-state imaging element, the cover structure being bonded to the solid-state imaging element via an adhesive, the cover structure being configured of an inorganic material.

(2) The imaging apparatus according to above (1), in which

the cover structure is a wafer level lens.

(3) The imaging apparatus according to above (1) or (2), in which

the cover structure includes glass.

(4) The imaging apparatus according to above (1) or (2), in which

the cover structure includes silicon or germanium.

(5) The imaging apparatus according to any one of above (1) to (4), in which

the non-flat surface of the cover structure has a shape obtained by cutting out an aspherical surface concentrically formed into a rectangular shape.

(6) The imaging apparatus according to any one of above (1) to (5), in which

the non-flat surface of the cover structure has a concave shape.

(7) The imaging apparatus according to above (6), in which, in the cover structure, a thickness of a thinnest portion is thinner than a height difference of a thickness on the non-flat surface.

(8) The imaging apparatus according to above (6) or (7), in which

the height difference of the thickness of the cover structure on the non-flat surface is thicker than the thickness of the solid-state imaging element.

(9) The imaging apparatus according to any one of above (1) to (5), in which

the non-flat surface of the cover structure has a convex shape.

(10) The imaging apparatus according to any one of above (1) to (9), in which

the cover structure includes an anti-reflection coating on a surface thereof.

(11) A method for manufacturing an imaging apparatus, the method including:

a procedure of forming an inorganic material on an upper layer of a solid-state imaging element; and

a procedure of processing a surface of the inorganic material into a non-flat surface.

(12) The method for manufacturing an imaging apparatus according to above (11), in which

the procedure of processing the surface of the inorganic material into the non-flat surface includes

a procedure of forming a degenerated layer on a surface of the inorganic material by laser processing or plasma processing; and

a procedure of removing the degenerated layer by etching.

(13) The method for manufacturing an imaging apparatus according to above (11), in which

the procedure of processing the surface of the inorganic material into the non-flat surface includes

a procedure of applying a photosensitive substance to the surface of the inorganic material and exposing the photosensitive substance to light; and

a procedure of removing an unnecessary portion of the surface of the inorganic material after exposure by etching.

(14) The method for manufacturing an imaging apparatus according to above (11), in which

the procedure of processing the surface of the inorganic material into the non-flat surface includes

a procedure of applying heat or light to deform the surface of the inorganic material; and

a procedure of removing an unnecessary portion after deformation of the surface of the inorganic material by etching.

(15) The method for manufacturing an imaging apparatus according to above (14), in which

the etching is catalytic etching.

### REFERENCE SIGNS LIST

100 Substrate
200 Solid-state imaging element
300 to 303 Adhesive
400 Cover structure
410 Protrusion
420 Overhang
431, 441, 451, 461 Inorganic material
432, 433 Degenerated layer
442, 446 to 448 Gray tone mask
443 Photosensitive resin
444 Mask
452, 454 Resist
453, 455, 462, 463 Replica mold
490 anti-reflection coating
521 Light shielding film

1. An imaging apparatus comprising:
a solid-state imaging element configured to generate a pixel signal by photoelectric conversion according to a light amount of incident light; and
a cover structure having a non-flat surface for focusing the incident light on a light receiving surface of the solid-state imaging element, the cover structure being bonded to the solid-state imaging element via an adhesive, the cover structure being configured of an inorganic material.

2. The imaging apparatus according to claim 1, wherein
the cover structure is a wafer level lens.

3. The imaging apparatus according to claim 1, wherein
the cover structure includes glass.

4. The imaging apparatus according to claim 1, wherein
the cover structure includes silicon or germanium.

5. The imaging apparatus according to claim 1, wherein
the non-flat surface of the cover structure has a shape obtained by cutting out an aspherical surface concentrically formed into a rectangular shape.

6. The imaging apparatus according to claim 1, wherein
the non-flat surface of the cover structure has a concave shape.

7. The imaging apparatus according to claim 6, wherein, in the cover structure, a thickness of a thinnest portion is thinner than a height difference of a thickness on the non-flat surface.

8. The imaging apparatus according to claim 6, wherein
the height difference of the thickness of the cover structure on the non-flat surface is thicker than the thickness of the solid-state imaging element.

9. The imaging apparatus according to claim 1, wherein
the non-flat surface of the cover structure has a convex shape.

10. The imaging apparatus according to claim 1, wherein
the cover structure includes an anti-reflection coating on a surface thereof.

11. A method for manufacturing an imaging apparatus, the method comprising:
a procedure of forming an inorganic material on an upper layer of a solid-state imaging element; and
a procedure of processing a surface of the inorganic material into a non-flat surface.

12. The method for manufacturing an imaging apparatus according to claim 11, wherein
the procedure of processing the surface of the inorganic material into the non-flat surface includes
a procedure of forming a degenerated layer on a surface of the inorganic material by laser processing or plasma processing; and
a procedure of removing the degenerated layer by etching.

13. The method for manufacturing an imaging apparatus according to claim 11, wherein
the procedure of processing the surface of the inorganic material into the non-flat surface includes
a procedure of applying a photosensitive substance to the surface of the inorganic material and exposing the photosensitive substance to light; and
a procedure of removing an unnecessary portion of the surface of the inorganic material after exposure by etching.

14. The method for manufacturing an imaging apparatus according to claim 11, wherein
the procedure of processing the surface of the inorganic material into the non-flat surface includes
a procedure of applying heat or light to deform the surface of the inorganic material; and
a procedure of removing an unnecessary portion after deformation of the surface of the inorganic material by etching.

15. The method for manufacturing an imaging apparatus according to claim 14, wherein
the etching is catalytic etching.
